(19) United States
(12) Patent Application Publication
(10) Pub. No.: US 2019/0107333 A1
(43) Pub. Date: Apr. 11, 2019

(54) HEAT PIPES, METHODS FOR TRANSFERRING HEAT USING HEAT PIPES, AND HEAT TRANSFER FLUIDS FOR USE IN HEAT PIPES

(71) Applicant: HONEYWELL INTERNATIONAL INC., Morris Plains, NJ (US)

(72) Inventors: Yongming Niu, Shanghai (CN); Enxin Lin, Shanghai (CN); Yong Zhou, Shanghai (CN); Hongxiang Huo, Shanghai (CN); Guanxing Zou, Shanghai (CN)

(21) Appl. No.: 16/137,990

(22) Filed: Sep. 22, 2018

Related U.S. Application Data
(60) Provisional application No. 62/562,005, filed on Sep. 22, 2017.
(60) Provisional application No. 62/607,397, filed on Dec. 19, 2017.

(51) Int. Cl. F28D 15/02; H01L 23/427; F28D 15/04

(52) U.S. Cl. CPC F28D 15/0266; F28D 15/046; F28D 15/0233; H01L 23/427

(57) ABSTRACT

The present invention also includes methods of transferring heat comprising: (a) providing a heat pipe comprising an evaporating section containing a liquid working fluid comprising at least about 60% by weight of cis 1-chloro-3,3,3-trifluoropropene and a condensing section containing a working fluid vapor comprising cis 1-chloro-3,3,3-trifluoropropene; (b) placing said evaporating section in thermal communication with a body, fluid, surface or the like to be cooled; and (c) placing said condensing section in thermal communication with a body, fluid, surface or the like to be heated.

### CROSS REFERENCE

The present invention is related to and claims the priority benefit of each of U.S. Provisional Application 62/562,005, filed Sep. 22, 2017 and U.S. Provisional Application 62/607,397, filed Dec. 19, 2017, each of which is incorporated herein by reference.

### FIELD

The present invention relates to heat pipes and to methods, systems and compositions which are used in or which use heat pipe(s).

### BACKGROUND

As used herein, the term “heat pipe” means a heat transfer device which includes liquid working fluid in an evaporating section and vaporous working fluid in a condensing section and which uses substantially only the motive force of vaporization to move the vaporous working fluid from the evaporating section to the condensing section and little or no energy input to move the liquid working fluid back to the evaporating section.

One of the most common types of heat pipes is depicted in Figure A, which is commonly known as a gravity-return-return or gravity-return-driven heat pipe or thermosyphon heat pipe, relies on the force of gravity-return to return the liquid working fluid from the condensing section to the evaporating section. As illustrated in Figure A, in a typical configuration the heat pipe is a sealed container arranged vertically with an evaporating section located below a partition and a condensing section located above the partition. The evaporating section contains a working fluid in liquid form that absorbs heat from the item, body or fluid to be cooled and is thereby boiled to form a vapor of the working fluid. Boiling of the working fluid in the evaporation section causes a pressure differential and drives the vapor into the condensing section. Vaporous working fluid in the condensing section releases heat to the chosen heat sink (for example, ambient air) and is thereby condensed to form liquid working fluid at or proximate to the inside surface of the container. This liquid then returns under the force of gravity-return to the evaporating section and joins the liquid working fluid contained there. As mentioned above, boiling increases the mass of vapor in the evaporating section, and since the mass of vapor is reduced in the condensing section, a pressure differential is created which drives the vapor from the boiling section to the condensing section, thus creating a continuous heat transfer cycle that requires no energy input (other than the heat absorbed in the cooling operation) to transport the working fluid.

In some applications it is desired to arrange the heat pipe horizontally or at an incline, and one common type of heat pipe for use in such applications is known as a capillary-return heat pipe, or wicking heat pipe, an example of which is shown in Figure B.

In an arrangement of the type shown in Figure B, heat is absorbed into the working fluid in the evaporating section (shown on the left in the Figure) causing the liquid to boil, which as described above provides a pressure differential to move the vapour to the condensing section. However, rather than relying solely on gravity-return to return condensed liquid working fluid, a wicking structure is provided adjacent to the container wall that causes, through capillary action, a flow of the condensed working fluid to return from the condensing section to the evaporating section.

As a result of the very high heat transfer coefficients for boiling and condensation, heat pipes are highly effective thermal conductors. Heat pipes are therefore used in many applications, particularly electronic device cooling, such as central processing unit (CPU) cooling, energy recovery such as data center cooling recovery between cold air and hot air and space craft thermal control such as satellite temperature control.

In addition to the gravity-return-return heat pipe and the capillary-return heat pipe described above, there are a number of other heat pipes which can be characterized depending on the mechanism which uses little or no additional energy to return the working fluid condensate to the evaporating section, as summarized in the table below:

| Methods of condensate return | Referred to As |
|---|---|
| Centripetal force | Rotating heat pipe |
| Electrokinetic force | Electrohydrodynamic heat pipe |
| | Electro-osmotic heat pipe |
| Magnetic forces | Magnetohydrodynamic heat pipe |
| | Magnetic fluid heat pipe |
| Osmotic forces | Osmotic heat pipe |
| Oscillate forces | Oscillating heat pipe |

One of the most commonly used working fluids for capillary-return heat pipes has been 1,1,1,2-tetrafluororethane (R-134a). Although R-134a has the desirable property of not contributing to ozone depletion, it has the undesirable property of having a relatively high Global Warming Potential (GWP) of about 1300. There is therefore a need in the art for a more desirable working fluid for capillary-return heat pipes, including the need to find a replacement for R-134a that has more environmentally acceptable properties while at the same time providing a working fluid with transport and heat transfer properties suitable for capillary-return heat pipe operation.

As explained in US 2004/0105233, there is a need in the information technology and computer industries for means to provide increasingly efficient and effective heat removal technologies. For example, portable electronic devices, such as notebook computers, smart phones, tablets, i-pads and the like are becoming lighter, thinner, shorter and/or smaller while at the same time possessing powerful calculation, communication and data processing capability. As a result, central processing units (CPUs) and other electronic components used in such devices have become more complicated in order to provide more powerful functions for users and application software, but these advances come at the price of higher power consumption, which in turn elevates the working temperature of those components. The high working temperature can cause instability in a working system, and especially in a small-sized portable device. In order to maintain the stability of modern CPUs and the like, it is increasingly more important to provide effective means for removing these higher levels of heat from increasingly small devices.

Generally, the heat generated by the CPU and the like must be dissipated by rejecting the heat to ambient air. Typically, this is done by bringing ambient air into the enclosure that contains the electronic components, either by forced or natural convection, and rejecting the heat to the air and then discharging the heated air from the device. Because notebook computers, tablets, i-pads and the like are generally intended for use both indoors and outdoors, amibient conditions can vary significantly. As ambient temperatures increase, the need for and the difficulty of obtaining cooling of the electronic components increases. Thus, for example, systems and devices must be able to remain stable even in high ambient temperature conditions. Accordingly, applicants have come to appreciate that devices for removing the heat, especially from electronic components and the like, are preferably able to operate as effectively, or nearly as effectively, in the most unfavorable conditions of high outside temperatures and full load of the components as in the more moderate ambient temperature conditions.

In many cities of the world, average summer temperatures can be 40° C. or higher. Moreover, the temperature of the air inside the device to which heat must be rejected is generally higher than the outside ambient air because it warms as it circulates inside the enclosure before it is expelled from the casing of the notebook or the like. Accordingly, the temperature of the air to which heat must be rejected can reach 50° C. and higher (see US 2004/0105233), and modern CPUs and other electronic components are designed to operate with maximum working temperatures of from about 60° C. to about 90° C. See, for example, US2002/0033247. In addition, even in situations in which electronic equipment is intended to be used in a temperature controlled environment, such as a server-room for example, it is possible even in such cases that the means for keeping the ambient air relatively cool (air conditioning, for example) could fail. In such a case, applicants have come to appreciate that a heat pipe for use in those and similar situations preferably can continue to operate effectively even if the ambient temperature were to increase into the range of 50° C. to 100° C.

Accordingly, applicants have come to appreciate that a significant advantage can be achieved by a heat removing device which is highly effective at removing heat from a body, fluid or component, particularly from an electronic device or component used in notebook, laptop, tablet, i-pad computing device, servers, desktop computers and the like, across an operating temperature range that includes temperatures above about 50° C., including in the range of from about 50° C. to about 100° C.

In addition, applicants have come to appreciate that advantage can be obtained by the discovery of a working fluid that is more environmentally acceptable than R-134a and is effective for use in both capillary-return and gravity-return-return heat pipes.

Development of a replacement working fluid for heat pipes, and in particular capillary-return heat pipes, and even more particularly capillary-return heat pipes for cooling of small electronic components, is a complex, difficult and unpredictable undertaking. This is due in large part to the need to operate the heat pipe with little or no energy input other than the heat absorbed while at the same time providing high efficiency heat transfer for the operating temperature range. By way of example, the following operating difficulties must be addressed and surmounted in order for a heat pipe to operate effectively with a new, replacement working fluid:
for both gravity-return return an capillary return designs, entrainment issues causes by the vapor and liquid moving in the same container in opposite directions, which can decrease or degrade the return of working fluid condensate to the evaporator section;
for both gravity-return return an capillary return designs, sonic flow issues, which can create a limit of the rate of vapor delivered from the evaporating section to the condensing section;
for capillary-return designs, ensuring that the working fluid liquid is able to create sufficient capillary pressure to effectively move the working fluid condensate from the condensate section to the evaporator section;
for capillary-return designs, the formation of vapor bubbles of the working fluid in the wick can cause unwanted hot spots in the evaporator section and obstruct or block return of the liquid from the condensing section to the evaporator section.

All of these operating considerations, and others, involve both the heat transfer properties and the transport properties of the working fluid, and the interrelationship of those properties, for both the liquid phases and the vapor phases. Whether the interrelationship of those properties will permit successful operation in a heat pipe, especially for working temperature ranges that exist for the cooling of small electronic components, generally cannot be determined reliably in advance of obtaining experimental data.

### BRIEF DESCRIPTION OF THE DRAWINGS

Figure A is a schematic representation of a gravity-return-return heat pipe.

Figure B is a schematic representation of a capillary-return heat pipe.

FIG. 1a is a schematic view of a thermosyphon heat pipe.

FIG. 1b is a schematic view of a vapor chamber/planar heat pipe.

FIG. 1c is a schematic view of a pulsating heat pipe.

FIG. 1d is a photograph of a capillary heat pipe showing the capillary material inside the heat pipe in cross section.

FIG. 1e is a photograph of a loop heat pipe.

FIG. 3a provides a comparison of Merit number with temperature for cis 1-chloro-3,3,3-trifluoropropene and R-134a in (a) a capillary return heat pipe and (b) a gravity-return return heat pipe in accordance with Examples hereof.

FIG. 3b provides a comparison of Merit number with temperature for cis 1-chloro-3,3,3-trifluoropropene and R-134a in (a) a capillary return heat pipe and (b) a gravity-return return heat pipe in accordance with the Examples hereof.

FIG. 4a provides a chart of evaporating temperature versus thermal resistance data according to Examples hereof.

FIG. 4b provides a chart of heat transfer capacity versus evaporator temperature differential data according to Examples hereof.

FIG. 5a provides a chart of heat transfer capacity versus evaporator temperature differential data according to Examples hereof.

FIG. 5b provides a chart of evaporating temperature versus evaporator temperature differential data according to Examples hereof.

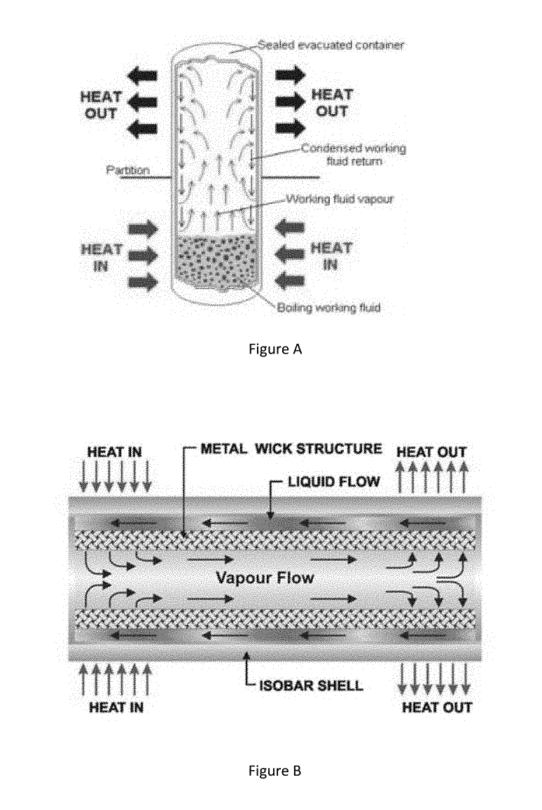

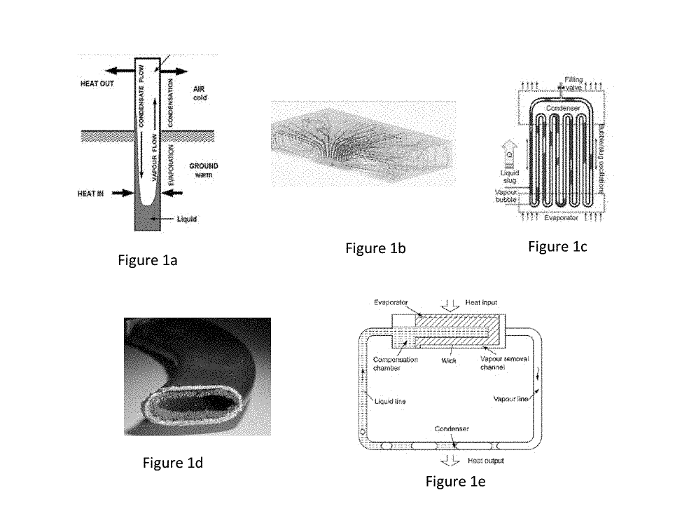

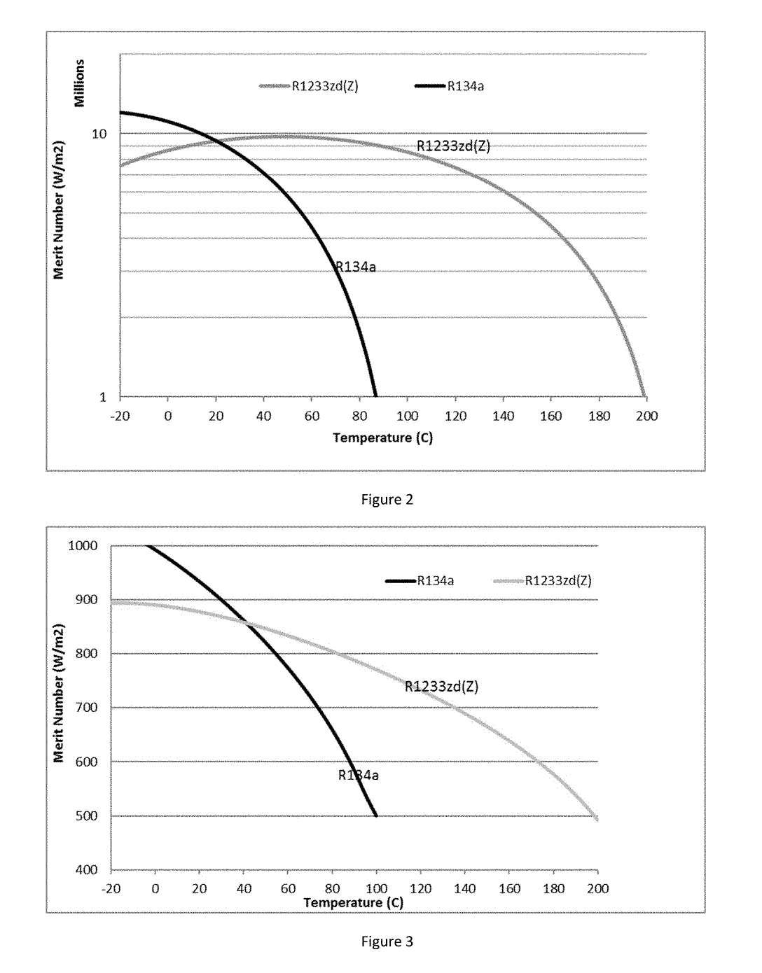

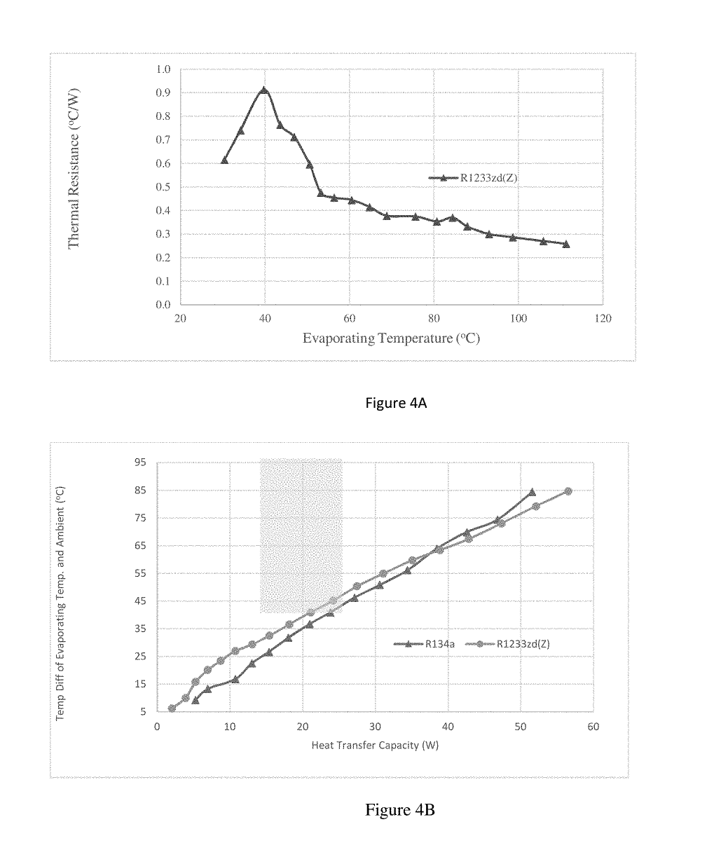

### SUMMARY

The present invention includes a heat pipe comprising a sealed container comprising:

(a) an inner space with an inner surface; said inner space comprising:
(i) an evaporating section at least in part by a wall of said container and containing a liquid working fluid comprising, or consisting essentially of, or consisting of at least about 60% by weight of cis 1-chloro-3,3,3-trifluoropropene in contact an inner surface of said wall,
(ii) a condensing section formed at least in part by said wall of said sealed container, said evaporating section being in fluid communication with said evaporating section and containing a working fluid vapor comprising cis 1-chloro-3,3,3-trifluoropropene in contact with an inner surface of said wall;
(b) an outer surface formed by at least a portion of said wall which forms said condensing section; and
(c) heat transfer enhancing projections extending from said outer surface.

The present invention also includes methods of transferring heat comprising:

(a) providing a heat pipe comprising an evaporating section containing a liquid working fluid comprising at least about 60% by weight of cis 1-chloro-3,3,3-trifluoropropene and a condensing section containing a working fluid vapor comprising cis 1-chloro-3,3,3-trifluoropropene;
(b) placing said evaporating section in thermal communication with a body, fluid, surface or the like to be cooled; and
(c) placing said condensing section in thermal communication with a body, fluid, surface or the like to be heated.

The body, fluid, surface or the like to be heated is sometimes referred to herein for convenience as a heat sink.

As used herein, the term “thermal communication” between a first body, fluid, surface or the like and a second body, fluid, surface or the like means that the first body and the second body are separated, if at all, only by thermally conductive materials so as to permit ready transfer of heat from the first body to the second body, as is well understood by those skilled in the art.

The present invention also includes a heat transfer system for transferring heat from an object or fluid to be cooled and a heat sink object or fluid, said system comprising a heat pipe comprising:

(a) an evaporating section containing a liquid working fluid comprising at least about 60% by weight of cis 1-chloro-3,3,3-trifluoropropene, said evaporating section being in heat transfer contact with said object or body to be cooled; and

(b) a condensing section containing a working fluid vapor comprising cis 1-chloro-3,3,3-trifluoropropene, said condensing section being in heat transfer contact with said heat sink.

### DETAILED DESCRIPTION

Applicants have unexpectedly found that the needs and advantages mentioned above, among others, can be achieved and/or that the heat pipe operational issues can be effectively overcome, according to the methods, systems, uses, articles and compositions of the present invention while at the same time providing improved performance from an environmental perspective compared to operation with R-134a.

As explained herein, applicants have found that unexpected advantages are achieved by use of working fluids in heat pipes that include at least 60% by weight of cis 1-chloro-3,3,3-trifluoropropene and that other components can be added to the working fluid in accordance with the teachings contained herein without negating those advantages, and the use of such heat pipes in methods and systems of the present invention with unexpected advantage.

### Heat Transfer Methods

The present invention includes methods of transferring heat from a body or fluid to be cooled to a heat sink, said method comprising: (a) providing a heat pipe comprising an evaporating section containing a liquid working fluid comprising at least about 60% by weight of cis 1-chloro-3,3,3-trifluoropropene and a condensing section containing a working fluid vapor comprising cis 1-chloro-3,3,3-trifluoropropene; (b) placing said evaporating section in thermal communication with the body or fluid to be cooled; and (c) placing said condensing section in thermal communication with the heat sink. For the purpose of convenience, heat transfer methods according to this paragraph are referred to herein as Heat Transfer Method 1.

The present invention includes methods of transferring heat which preferably comprise: (a) providing a heat pipe comprising an evaporating section containing a liquid working fluid comprising at least about 70% by weight of cis 1-chloro-3,3,3-trifluoropropene and a condensing section containing a working fluid vapor comprising cis 1-chloro-3,3,3-trifluoropropene; (b) placing said evaporating section in thermal communication with a body, fluid, surface or the like to be cooled; and (c) placing said condensing section in thermal communication with a heat sink. For the purpose of convenience, heat transfer methods according to this paragraph are referred to herein as Heat Transfer Method 2.

The present invention includes methods of transferring heat which preferably comprise: (a) providing a heat pipe comprising an evaporating section containing a liquid working fluid comprising at least about 90% by weight of cis 1-chloro-3,3,3-trifluoropropene and a condensing section containing a working fluid vapor comprising cis 1-chloro-3,3,3-trifluoropropene; (b) placing said evaporating section in thermal communication with a body, fluid, surface or the like to be cooled; and (c) placing said condensing section in thermal communication with a heat sink. For the purpose of convenience, heat transfer methods according to this paragraph are referred to herein as Heat

Transfer Method 3.

The present invention includes methods of transferring heat which preferably comprise: (a) providing a heat pipe comprising an evaporating section containing a liquid working fluid comprising at least about 95% by weight of cis 1-chloro-3,3,3-trifluoropropene and a condensing section containing a working fluid vapor comprising cis 1-chloro-3,3,3-trifluoropropene; (b) placing said evaporating section in thermal communication with a body, fluid, surface or the like to be cooled; and (c) placing said condensing section in thermal communication with a heat sink. For the purpose of convenience, heat transfer methods according to this paragraph are referred to herein as Heat Transfer Method 4.

The present invention includes methods of transferring heat which preferably comprise: (a) providing a heat pipe comprising an evaporating section containing a liquid working fluid comprising at least about 97% by weight of cis 1-chloro-3,3,3-trifluoropropene and a condensing section containing a working fluid vapor comprising cis 1-chloro-3,3,3-trifluoropropene; (b) placing said evaporating section in thermal communication with a body, fluid, surface or the like to be cooled; and (c) placing said condensing section in thermal communication with a heat sink. For the purpose of convenience, heat transfer methods according to this paragraph are referred to herein as Heat Transfer Method 5.

The present invention includes methods of transferring heat which preferably comprise: (a) providing a heat pipe comprising an evaporating section containing a liquid working fluid comprising at least about 99.5% by weight of cis 1-chloro-3,3,3-trifluoropropene and a condensing section containing a working fluid vapor comprising cis 1-chloro-3,3,3-trifluoropropene; (b) placing said evaporating section in thermal communication with a body, fluid, surface or the like to be cooled; and (c) placing said condensing section in thermal communication with a heat sink. For the purpose of convenience, heat transfer methods according to this paragraph are referred to herein as Heat Transfer Method 6.

The present invention includes methods of transferring heat which preferably comprise: (a) providing a heat pipe comprising an evaporating section containing a liquid working fluid provides the use of a composition consisting essentially of cis 1-chloro-3,3,3-trifluoropropene and a condensing section containing a working fluid vapor consisting essentially of cis 1-chloro-3,3,3-trifluoropropene; (b) placing said evaporating section in thermal communication with a body, fluid, surface or the like to be cooled; and (c) placing said condensing section in thermal communication with a heat sink. For the purpose of convenience, heat transfer methods according to this paragraph are referred to herein as Heat Transfer Method 7.

The present invention includes methods of transferring heat which preferably comprise: (a) providing a heat pipe comprising an evaporating section containing a liquid working fluid consisting of cis 1-chloro-3,3,3-trifluoropropene and a condensing section containing a working fluid vapor consisting of cis 1-chloro-3,3,3-trifluoropropene; (b) placing said evaporating section in thermal communication with a body, fluid, surface or the like to be cooled; and (c) placing said condensing section in thermal communication with a heat sink. For the purpose of convenience, heat transfer methods according to this paragraph are referred to herein as Heat Transfer Method 8.

The present invention includes Heat Transfer Method 1 wherein the operating temperature range of the heat pipe is at least about 20° C.

As used herein, the term “operating temperature range” refers to a temperature range that encompasses the temperature of the working fluid in the evaporating section.

The present invention includes Heat Transfer Method 1 wherein the operating temperature range of the heat pipe is from about 20° C. to about 100° C.

The present invention includes Heat Transfer Method 1 wherein the heat pipe is a gravity-return heat pipe and the operating temperature range of the heat pipe is from about 20° C. to about 100° C.

As the term is used herein, “gravity-return-return heat pipe” means a heat pipe in which the liquid working fluid returns to the evaporator section from the condenser section, at least in part and preferably in substantial part, by the action of gravity-return on the working fluid.

The present invention includes Heat Transfer Method 1 wherein the heat pipe is a gravity-return-return heat pipe and the operating temperature range of the heat pipe is from about 50° C. to about 100° C.

The present invention includes Heat Transfer Method 1 wherein the heat pipe is a gravity-return-return heat pipe, the operating temperature range of the heat pipe is from about 50° C. to about 100° C. and wherein said heat sink is at a temperature of from about 15° C. to about 80° C.

The present invention includes Heat Transfer Method 1 wherein the heat pipe is a gravity-return-return heat pipe, the operating temperature range of the heat pipe is from about 50° C. to about 100° C. and wherein said heat sink is at a temperature of from about 15° C. to about 40° C.

The present invention includes Heat Transfer Method 1 wherein the heat pipe is a gravity-return-return heat pipe, the operating temperature range of the heat pipe is from about 50° C. to about 100° C. and wherein said heat sink is at a temperature of from about 20° C. to about 30° C.

The present invention includes Heat Transfer Method 1 wherein the heat pipe is a gravity-return-return heat pipe and the operating temperature range of the heat pipe is from about 70° C. to about 100° C.

The present invention includes Heat Transfer Method 1 wherein the heat pipe is a gravity-return-return heat pipe, the operating temperature range of the heat pipe is from about 70° C. to about 100° C. and wherein said heat sink is at a temperature of from about 15° C. to about 80° C.

The present invention includes Heat Transfer Method 1 wherein the heat pipe is a gravity-return-return heat pipe, the operating temperature range of the heat pipe is from about 70° C. to about 100° C. and wherein said heat sink is at a temperature of from about 15° C. to about 40° C.

The present invention includes Heat Transfer Method 1 wherein the heat pipe is a gravity-return-return heat pipe, the operating temperature range of the heat pipe is from about 70° C. to about 100° C. and wherein said heat sink is at a temperature of from about 20° C. to about 30° C.

The present invention includes Heat Transfer Method 1 wherein the heat pipe is a gravity-return-return heat pipe and the operating temperature range of the heat pipe is from about 85° C. to about 95° C.

The present invention includes Heat Transfer Method 1 wherein the heat pipe is a gravity-return-return heat pipe, the operating temperature range of the heat pipe is from about 85° C. to about 100° C. and wherein said heat sink is at a temperature of from about 15° C. to about 80° C.

The present invention includes Heat Transfer Method 1 wherein the heat pipe is a gravity-return-return heat pipe, the operating temperature range of the heat pipe is from about 85° C. to about 100° C. and wherein said heat sink is at a temperature of from about 15° C. to about 40° C.

The present invention includes Heat Transfer Method 1 wherein the heat pipe is a gravity-return-return heat pipe, the operating temperature range of the heat pipe is from about 85° C. to about 100° C. and wherein said heat sink is at a temperature of from about 20° C. to about 30° C.

The present invention includes Heat Transfer Method 1 wherein the heat pipe is a gravity-return-return heat pipe and the operating temperature range of the heat pipe is from about 85° C. to about 95° C.

The present invention includes Heat Transfer Method 1 wherein the heat pipe is a gravity-return-return heat pipe, the operating temperature range of the heat pipe is from about 85° C. to about 95° C. and wherein said heat sink is at a temperature of from about 15° C. to about 80° C.

The present invention includes Heat Transfer Method 1 wherein the heat pipe is a gravity-return-return heat pipe, the operating temperature range of the heat pipe is from about 85° C. to about 95° C. and wherein said heat sink is at a temperature of from about 15° C. to about 40° C.

The present invention includes Heat Transfer Method 1 wherein the heat pipe is a gravity-return-return heat pipe, the operating temperature range of the heat pipe is from about 85° C. to about 95° C. and wherein said heat sink is at a temperature of from about 20° C. to about 30° C.

The present invention includes Heat Transfer Method 1 wherein the heat pipe is a gravity-return-return heat pipe and the operating temperature range of the heat pipe is greater than about 85° C.

The present invention includes Heat Transfer Method 1 wherein the heat pipe is a gravity-return-return heat pipe, the operating temperature range of the heat pipe is greater than about 85° C. and wherein said heat sink is at a temperature of from about 15° C. to about 80° C.

The present invention includes Heat Transfer Method 1 wherein the heat pipe is a gravity-return-return heat pipe, the operating temperature range of the heat pipe is greater than about 85° C. and wherein said heat sink is at a temperature of from about 15° C. to about 40° C.

The present invention includes Heat Transfer Method 1 wherein the heat pipe is a gravity-return-return heat pipe, the operating temperature range of the heat pipe greater than about 85° C. and wherein said heat sink is at a temperature of from about 20° C. to about 30° C.

The present invention includes Heat Transfer Method 1 wherein the heat pipe is a gravity-return-return heat pipe and the operating temperature range of the heat pipe is greater than about 88° C.

The present invention includes Heat Transfer Method 1 wherein the heat pipe is a gravity-return-return heat pipe, the operating temperature range of the heat pipe is greater than about 88° C. and wherein said heat sink is at a temperature of from about 15° C. to about 80° C.

The present invention includes Heat Transfer Method 1 wherein the heat pipe is a gravity-return-return heat pipe, the operating temperature range of the heat pipe is greater than about 88° C. and wherein said heat sink is at a temperature of from about 15° C. to about 40° C.

The present invention includes Heat Transfer Method 1 wherein the heat pipe is a gravity-return-return heat pipe, the operating temperature range of the heat pipe greater than about 88° C. and wherein said heat sink is at a temperature of from about 20° C. to about 30° C.

The present invention includes Heat Transfer Method 1 wherein the heat pipe is a gravity-return-return heat pipe and in which the heat pipe operates a heat capacity ratio of 1 or greater. As used herein, heat capacity ratio means the ratio of the heat capacity of the working fluid in the heat pipe compared to the heat capacity of the heat pipe with the working fluid consisting of R-134a.

The present invention includes Heat Transfer Method 1 wherein the heat pipe is a gravity-return-return heat pipe and has a thermal resistance as measured as defined herein of about 0.5° C. per watt or less.

The present invention includes Heat Transfer Method 2 wherein the operating temperature range of the heat pipe is from about 20° C. to about 100° C.

The present invention includes Heat Transfer Method 2 wherein the heat pipe is a gravity-return-return heat pipe and the operating temperature range of the heat pipe is from about 20° C. to about 100° C.

The present invention includes Heat Transfer Method 2 wherein the heat pipe is a gravity-return-return heat pipe and the operating temperature range of the heat pipe is from about 50° C. to about 100° C.

The present invention includes Heat Transfer Method 2 wherein the heat pipe is a gravity-return-return heat pipe, the operating temperature range of the heat pipe is from about 50° C. to about 100° C. and wherein said heat sink is at a temperature of from about 15° C. to about 80° C.

The present invention includes Heat Transfer Method 2 wherein the heat pipe is a gravity-return-return heat pipe, the operating temperature range of the heat pipe is from about 50° C. to about 100° C. and wherein said heat sink is at a temperature of from about 15° C. to about 40° C.

The present invention includes Heat Transfer Method 2 wherein the heat pipe is a gravity-return-return heat pipe, the operating temperature range of the heat pipe is from about 50° C. to about 100° C. and wherein said heat sink is at a temperature of from about 20° C. to about 30° C.

The present invention includes Heat Transfer Method 2 wherein the heat pipe is a gravity-return-return heat pipe and the operating temperature range of the heat pipe is from about 70° C. to about 100° C.

The present invention includes Heat Transfer Method 2 wherein the heat pipe is a gravity-return-return heat pipe, the operating temperature range of the heat pipe is from about 70° C. to about 100° C. and wherein said heat sink is at a temperature of from about 15° C. to about 80° C.

The present invention includes Heat Transfer Method 2 wherein the heat pipe is a gravity-return-return heat pipe, the operating temperature range of the heat pipe is from about 70° C. to about 100° C. and wherein said heat sink is at a temperature of from about 15° C. to about 40° C.

The present invention includes Heat Transfer Method 2 wherein the heat pipe is a gravity-return-return heat pipe, the operating temperature range of the heat pipe is from about 70° C. to about 100° C. and wherein said heat sink is at a temperature of from about 20° C. to about 30° C.

The present invention includes Heat Transfer Method 2 wherein the heat pipe is a gravity-return-return heat pipe and the operating temperature range of the heat pipe is from about 85° C. to about 95° C.

The present invention includes Heat Transfer Method 2 wherein the heat pipe is a gravity-return-return heat pipe, the operating temperature range of the heat pipe is from about 85° C. to about 100° C. and wherein said heat sink is at a temperature of from about 15° C. to about 80° C.

The present invention includes Heat Transfer Method 2 wherein the heat pipe is a gravity-return-return heat pipe, the operating temperature range of the heat pipe is from about 85° C. to about 100° C. and wherein said heat sink is at a temperature of from about 15° C. to about 40° C.

The present invention includes Heat Transfer Method 2 wherein the heat pipe is a gravity-return-return heat pipe, the operating temperature range of the heat pipe is from about 85° C. to about 100° C. and wherein said heat sink is at a temperature of from about 20° C. to about 30° C.

The present invention includes Heat Transfer Method 2 wherein the heat pipe is a gravity-return-return heat pipe and the operating temperature range of the heat pipe is from about 85° C. to about 95° C.

The present invention includes Heat Transfer Method 2 wherein the heat pipe is a gravity-return-return heat pipe, the operating temperature range of the heat pipe is from about 85° C. to about 95° C. and wherein said heat sink is at a temperature of from about 15° C. to about 80° C.

The present invention includes Heat Transfer Method 2 wherein the heat pipe is a gravity-return-return heat pipe, the operating temperature range of the heat pipe is from about 85° C. to about 95° C. and wherein said heat sink is at a temperature of from about 15° C. to about 40° C.

The present invention includes Heat Transfer Method 2 wherein the heat pipe is a gravity-return-return heat pipe, the operating temperature range of the heat pipe is from about 85° C. to about 95° C. and wherein said heat sink is at a temperature of from about 20° C. to about 30° C.

The present invention includes Heat Transfer Method 2 wherein the heat pipe is a gravity-return-return heat pipe and the operating temperature range of the heat pipe is greater than about 85° C.

The present invention includes Heat Transfer Method 2 wherein the heat pipe is a gravity-return-return heat pipe, the operating temperature range of the heat pipe is greater than about 85° C. and wherein said heat sink is at a temperature of from about 15° C. to about 80° C.

The present invention includes Heat Transfer Method 2 wherein the heat pipe is a gravity-return-return heat pipe, the operating temperature range of the heat pipe is greater than about 85° C. and wherein said heat sink is at a temperature of from about 15° C. to about 40° C.

The present invention includes Heat Transfer Method 2 wherein the heat pipe is a gravity-return-return heat pipe, the operating temperature range of the heat pipe greater than about 85° C. and wherein said heat sink is at a temperature of from about 20° C. to about 30° C.

The present invention includes Heat Transfer Method 2 wherein the heat pipe is a gravity-return-return heat pipe and the operating temperature range of the heat pipe is greater than about 88° C.

The present invention includes Heat Transfer Method 2 wherein the heat pipe is a gravity-return-return heat pipe, the operating temperature range of the heat pipe is greater than about 88° C. and wherein said heat sink is at a temperature of from about 15° C. to about 80° C.

The present invention includes Heat Transfer Method 2 wherein the heat pipe is a gravity-return-return heat pipe, the operating temperature range of the heat pipe is greater than about 88° C. and wherein said heat sink is at a temperature of from about 15° C. to about 40° C.

The present invention includes Heat Transfer Method 2 wherein the heat pipe is a gravity-return-return heat pipe, the operating temperature range of the heat pipe greater than about 88° C. and wherein said heat sink is at a temperature of from about 20° C. to about 30° C.

The present invention includes Heat Transfer Method 2 wherein the heat pipe is a gravity-return-return heat pipe and in which the heat pipe operates a heat capacity ratio of 1 or greater. As used herein, heat capacity ratio means the ratio of the heat capacity of the working fluid in the heat pipe compared to the heat capacity of the heat pipe with the working fluid consisting of R-134a.

The present invention includes Heat Transfer Method 2 wherein the heat pipe is a gravity-return-return heat pipe and has a thermal resistance as measured in Example 5 hereof of about 0.5° C. per watt or less.

The present invention includes Heat Transfer Method 3 wherein the operating temperature range of the heat pipe is from about 20° C. to about 100° C.

The present invention includes Heat Transfer Method 3 wherein the heat pipe is a gravity-return-return heat pipe and the operating temperature range of the heat pipe is from about 20° C. to about 100° C.

The present invention includes Heat Transfer Method 3 wherein the heat pipe is a gravity-return-return heat pipe and the operating temperature range of the heat pipe is from about 50° C. to about 100° C.

The present invention includes Heat Transfer Method 3 wherein the heat pipe is a gravity-return-return heat pipe, the operating temperature range of the heat pipe is from about 50° C. to about 100° C. and wherein said heat sink is at a temperature of from about 15° C. to about 80° C.

The present invention includes Heat Transfer Method 3 wherein the heat pipe is a gravity-return-return heat pipe, the operating temperature range of the heat pipe is from about 50° C. to about 100° C. and wherein said heat sink is at a temperature of from about 15° C. to about 40° C.

The present invention includes Heat Transfer Method 3 wherein the heat pipe is a gravity-return-return heat pipe, the operating temperature range of the heat pipe is from about 50° C. to about 100° C. and wherein said heat sink is at a temperature of from about 20° C. to about 30° C.

The present invention includes Heat Transfer Method 3 wherein the heat pipe is a gravity-return-return heat pipe and the operating temperature range of the heat pipe is from about 70° C. to about 100° C.

The present invention includes Heat Transfer Method 3 wherein the heat pipe is a gravity-return-return heat pipe, the operating temperature range of the heat pipe is from about 70° C. to about 100° C. and wherein said heat sink is at a temperature of from about 15° C. to about 80° C.

The present invention includes Heat Transfer Method 3 wherein the heat pipe is a gravity-return-return heat pipe, the operating temperature range of the heat pipe is from about 70° C. to about 100° C. and wherein said heat sink is at a temperature of from about 15° C. to about 40° C.

The present invention includes Heat Transfer Method 3 wherein the heat pipe is a gravity-return-return heat pipe, the operating temperature range of the heat pipe is from about 70° C. to about 100° C. and wherein said heat sink is at a temperature of from about 20° C. to about 30° C.

The present invention includes Heat Transfer Method 3 wherein the heat pipe is a gravity-return-return heat pipe and the operating temperature range of the heat pipe is from about 85° C. to about 95° C.

The present invention includes Heat Transfer Method 3 wherein the heat pipe is a gravity-return-return heat pipe, the operating temperature range of the heat pipe is from about 85° C. to about 100° C. and wherein said heat sink is at a temperature of from about 15° C. to about 80° C.

The present invention includes Heat Transfer Method 3 wherein the heat pipe is a gravity-return-return heat pipe, the operating temperature range of the heat pipe is from about 85° C. to about 100° C. and wherein said heat sink is at a temperature of from about 15° C. to about 40° C.

The present invention includes Heat Transfer Method 3 wherein the heat pipe is a gravity-return-return heat pipe, the operating temperature range of the heat pipe is from about 85° C. to about 100° C. and wherein said heat sink is at a temperature of from about 20° C. to about 30° C.

The present invention includes Heat Transfer Method 3 wherein the heat pipe is a gravity-return-return heat pipe and the operating temperature range of the heat pipe is from about 85° C. to about 95° C.

The present invention includes Heat Transfer Method 3 wherein the heat pipe is a gravity-return-return heat pipe, the operating temperature range of the heat pipe is from about 85° C. to about 95° C. and wherein said heat sink is at a temperature of from about 15° C. to about 80° C.

The present invention includes Heat Transfer Method 3 wherein the heat pipe is a gravity-return-return heat pipe, the operating temperature range of the heat pipe is from about 85° C. to about 95° C. and wherein said heat sink is at a temperature of from about 15° C. to about 40° C.

The present invention includes Heat Transfer Method 3 wherein the heat pipe is a gravity-return-return heat pipe, the operating temperature range of the heat pipe is from about 85° C. to about 95° C. and wherein said heat sink is at a temperature of from about 20° C. to about 30° C.

The present invention includes Heat Transfer Method 3 wherein the heat pipe is a gravity-return-return heat pipe and the operating temperature range of the heat pipe is greater than about 85° C.

The present invention includes Heat Transfer Method 3 wherein the heat pipe is a gravity-return-return heat pipe, the operating temperature range of the heat pipe is greater than about 85° C. and wherein said heat sink is at a temperature of from about 15° C. to about 80° C.

The present invention includes Heat Transfer Method 3 wherein the heat pipe is a gravity-return-return heat pipe, the operating temperature range of the heat pipe is greater than about 85° C. and wherein said heat sink is at a temperature of from about 15° C. to about 40° C.

The present invention includes Heat Transfer Method 3 wherein the heat pipe is a gravity-return-return heat pipe, the operating temperature range of the heat pipe greater than about 85° C. and wherein said heat sink is at a temperature of from about 20° C. to about 30° C.

The present invention includes Heat Transfer Method 3 wherein the heat pipe is a gravity-return-return heat pipe and the operating temperature range of the heat pipe is greater than about 88° C.

The present invention includes Heat Transfer Method 3 wherein the heat pipe is a gravity-return-return heat pipe, the operating temperature range of the heat pipe is greater than about 88° C. and wherein said heat sink is at a temperature of from about 15° C. to about 80° C.

The present invention includes Heat Transfer Method 3 wherein the heat pipe is a gravity-return-return heat pipe, the operating temperature range of the heat pipe is greater than about 88° C. and wherein said heat sink is at a temperature of from about 15° C. to about 40° C.

The present invention includes Heat Transfer Method 3 wherein the heat pipe is a gravity-return-return heat pipe, the operating temperature range of the heat pipe greater than about 88° C. and wherein said heat sink is at a temperature of from about 20° C. to about 30° C.

The present invention includes Heat Transfer Method 3 wherein the heat pipe is a gravity-return-return heat pipe and in which the heat pipe operates a heat capacity ratio of 1 or greater. As used herein, heat capacity ratio means the ratio of the heat capacity of the working fluid in the heat pipe compared to the heat capacity of the heat pipe with the working fluid consisting of R-134a.

The present invention includes Heat Transfer Method 3 wherein the heat pipe is a gravity-return-return heat pipe and has a thermal resistance as measured in Example 5 hereof of about 0.5° C. per watt or less.

The present invention includes Heat Transfer Method 4 wherein the operating temperature range of the heat pipe is from about 20° C. to about 100° C.

The present invention includes Heat Transfer Method 4 wherein the heat pipe is a gravity-return-return heat pipe and the operating temperature range of the heat pipe is from about 20° C. to about 100° C.

The present invention includes Heat Transfer Method 4 wherein the heat pipe is a gravity-return-return heat pipe and the operating temperature range of the heat pipe is from about 50° C. to about 100° C.

The present invention includes Heat Transfer Method 4 wherein the heat pipe is a gravity-return-return heat pipe, the operating temperature range of the heat pipe is from about 50° C. to about 100° C. and wherein said heat sink is at a temperature of from about 15° C. to about 80° C.

The present invention includes Heat Transfer Method 4 wherein the heat pipe is a gravity-return-return heat pipe, the operating temperature range of the heat pipe is from about 50° C. to about 100° C. and wherein said heat sink is at a temperature of from about 15° C. to about 40° C.

The present invention includes Heat Transfer Method 4 wherein the heat pipe is a gravity-return-return heat pipe, the operating temperature range of the heat pipe is from about 50° C. to about 100° C. and wherein said heat sink is at a temperature of from about 20° C. to about 30° C.

The present invention includes Heat Transfer Method 4 wherein the heat pipe is a gravity-return-return heat pipe and the operating temperature range of the heat pipe is from about 70° C. to about 100° C.

The present invention includes Heat Transfer Method 4 wherein the heat pipe is a gravity-return-return heat pipe, the operating temperature range of the heat pipe is from about 70° C. to about 100° C. and wherein said heat sink is at a temperature of from about 15° C. to about 80° C.

The present invention includes Heat Transfer Method 4 wherein the heat pipe is a gravity-return-return heat pipe, the operating temperature range of the heat pipe is from about 70° C. to about 100° C. and wherein said heat sink is at a temperature of from about 15° C. to about 40° C.

The present invention includes Heat Transfer Method 4 wherein the heat pipe is a gravity-return-return heat pipe, the operating temperature range of the heat pipe is from about 70° C. to about 100° C. and wherein said heat sink is at a temperature of from about 20° C. to about 30° C.

The present invention includes Heat Transfer Method 4 wherein the heat pipe is a gravity-return-return heat pipe and the operating temperature range of the heat pipe is from about 85° C. to about 95° C.

The present invention includes Heat Transfer Method 4 wherein the heat pipe is a gravity-return-return heat pipe, the operating temperature range of the heat pipe is from about 85° C. to about 100° C. and wherein said heat sink is at a temperature of from about 15° C. to about 80° C.

The present invention includes Heat Transfer Method 4 wherein the heat pipe is a gravity-return-return heat pipe, the operating temperature range of the heat pipe is from about 85° C. to about 100° C. and wherein said heat sink is at a temperature of from about 15° C. to about 40° C.

The present invention includes Heat Transfer Method 4 wherein the heat pipe is a gravity-return-return heat pipe, the operating temperature range of the heat pipe is from about 85° C. to about 100° C. and wherein said heat sink is at a temperature of from about 20° C. to about 30° C.

The present invention includes Heat Transfer Method 4 wherein the heat pipe is a gravity-return-return heat pipe and the operating temperature range of the heat pipe is from about 85° C. to about 95° C.

The present invention includes Heat Transfer Method 4 wherein the heat pipe is a gravity-return-return heat pipe, the operating temperature range of the heat pipe is from about 85° C. to about 95° C. and wherein said heat sink is at a temperature of from about 15° C. to about 80° C.

The present invention includes Heat Transfer Method 4 wherein the heat pipe is a gravity-return-return heat pipe, the operating temperature range of the heat pipe is from about 85° C. to about 95° C. and wherein said heat sink is at a temperature of from about 15° C. to about 40° C.

The present invention includes Heat Transfer Method 4 wherein the heat pipe is a gravity-return-return heat pipe, the operating temperature range of the heat pipe is from about 85° C. to about 95° C. and wherein said heat sink is at a temperature of from about 20° C. to about 30° C.

The present invention includes Heat Transfer Method 4 wherein the heat pipe is a gravity-return-return heat pipe and the operating temperature range of the heat pipe is greater than about 85° C.

The present invention includes Heat Transfer Method 4 wherein the heat pipe is a gravity-return-return heat pipe, the operating temperature range of the heat pipe is greater than about 85° C. and wherein said heat sink is at a temperature of from about 15° C. to about 80° C.

The present invention includes Heat Transfer Method 4 wherein the heat pipe is a gravity-return-return heat pipe, the operating temperature range of the heat pipe is greater than about 85° C. and wherein said heat sink is at a temperature of from about 15° C. to about 40° C.

The present invention includes Heat Transfer Method 4 wherein the heat pipe is a gravity-return-return heat pipe, the operating temperature range of the heat pipe greater than about 85° C. and wherein said heat sink is at a temperature of from about 20° C. to about 30° C.

The present invention includes Heat Transfer Method 4 wherein the heat pipe is a gravity-return-return heat pipe and the operating temperature range of the heat pipe is greater than about 88° C.

The present invention includes Heat Transfer Method 4 wherein the heat pipe is a gravity-return-return heat pipe, the operating temperature range of the heat pipe is greater than about 88° C. and wherein said heat sink is at a temperature of from about 15° C. to about 80° C.

The present invention includes Heat Transfer Method 4 wherein the heat pipe is a gravity-return-return heat pipe, the operating temperature range of the heat pipe is greater than about 88° C. and wherein said heat sink is at a temperature of from about 15° C. to about 40° C.

The present invention includes Heat Transfer Method 4 wherein the heat pipe is a gravity-return-return heat pipe, the operating temperature range of the heat pipe greater than about 88° C. and wherein said heat sink is at a temperature of from about 20° C. to about 30° C.

The present invention includes Heat Transfer Method 4 wherein the heat pipe is a gravity-return-return heat pipe and in which the heat pipe operates a heat capacity ratio of 1 or greater. As used herein, heat capacity ratio means the ratio of the heat capacity of the working fluid in the heat pipe compared to the heat capacity of the heat pipe with the working fluid consisting of R-134a.

The present invention includes Heat Transfer Method 4 wherein the heat pipe is a gravity-return-return heat pipe and has a thermal resistance as measured in Example 5 hereof of about 0.5° C. per watt or less.

The present invention includes Heat Transfer Method 5 wherein the operating temperature range of the heat pipe is from about 20° C. to about 100° C.

The present invention includes Heat Transfer Method 5 wherein the heat pipe is a gravity-return-return heat pipe and the operating temperature range of the heat pipe is from about 20° C. to about 100° C.

The present invention includes Heat Transfer Method 5 wherein the heat pipe is a gravity-return-return heat pipe and the operating temperature range of the heat pipe is from about 50° C. to about 100° C.

The present invention includes Heat Transfer Method 5 wherein the heat pipe is a gravity-return-return heat pipe, the operating temperature range of the heat pipe is from about 50° C. to about 100° C. and wherein said heat sink is at a temperature of from about 15° C. to about 80° C.

The present invention includes Heat Transfer Method 5 wherein the heat pipe is a gravity-return-return heat pipe, the operating temperature range of the heat pipe is from about 50° C. to about 100° C. and wherein said heat sink is at a temperature of from about 15° C. to about 40° C.

The present invention includes Heat Transfer Method 5 wherein the heat pipe is a gravity-return-return heat pipe, the operating temperature range of the heat pipe is from about 50° C. to about 100° C. and wherein said heat sink is at a temperature of from about 20° C. to about 30° C.

The present invention includes Heat Transfer Method 5 wherein the heat pipe is a gravity-return-return heat pipe and the operating temperature range of the heat pipe is from about 70° C. to about 100° C.

The present invention includes Heat Transfer Method 5 wherein the heat pipe is a gravity-return-return heat pipe, the operating temperature range of the heat pipe is from about 70° C. to about 100° C. and wherein said heat sink is at a temperature of from about 15° C. to about 80° C.

The present invention includes Heat Transfer Method 5 wherein the heat pipe is a gravity-return-return heat pipe, the operating temperature range of the heat pipe is from about 70° C. to about 100° C. and wherein said heat sink is at a temperature of from about 15° C. to about 40° C.

The present invention includes Heat Transfer Method 5 wherein the heat pipe is a gravity-return-return heat pipe, the operating temperature range of the heat pipe is from about 70° C. to about 100° C. and wherein said heat sink is at a temperature of from about 20° C. to about 30° C.

The present invention includes Heat Transfer Method 5 wherein the heat pipe is a gravity-return-return heat pipe and the operating temperature range of the heat pipe is from about 85° C. to about 95° C.

The present invention includes Heat Transfer Method 5 wherein the heat pipe is a gravity-return-return heat pipe, the operating temperature range of the heat pipe is from about 85° C. to about 100° C. and wherein said heat sink is at a temperature of from about 15° C. to about 80° C.

The present invention includes Heat Transfer Method 5 wherein the heat pipe is a gravity-return-return heat pipe, the operating temperature range of the heat pipe is from about 85° C. to about 100° C. and wherein said heat sink is at a temperature of from about 15° C. to about 40° C.

The present invention includes Heat Transfer Method 5 wherein the heat pipe is a gravity-return-return heat pipe, the operating temperature range of the heat pipe is from about 85° C. to about 100° C. and wherein said heat sink is at a temperature of from about 20° C. to about 30° C.

The present invention includes Heat Transfer Method 5 wherein the heat pipe is a gravity-return-return heat pipe and the operating temperature range of the heat pipe is from about 85° C. to about 95° C.

The present invention includes Heat Transfer Method 5 wherein the heat pipe is a gravity-return-return heat pipe, the operating temperature range of the heat pipe is from about 85° C. to about 95° C. and wherein said heat sink is at a temperature of from about 15° C. to about 80° C.

The present invention includes Heat Transfer Method 5 wherein the heat pipe is a gravity-return-return heat pipe, the operating temperature range of the heat pipe is from about 85° C. to about 95° C. and wherein said heat sink is at a temperature of from about 15° C. to about 40° C.

The present invention includes Heat Transfer Method 5 wherein the heat pipe is a gravity-return-return heat pipe, the operating temperature range of the heat pipe is from about 85° C. to about 95° C. and wherein said heat sink is at a temperature of from about 20° C. to about 30° C.

The present invention includes Heat Transfer Method 5 wherein the heat pipe is a gravity-return-return heat pipe and the operating temperature range of the heat pipe is greater than about 85° C.

The present invention includes Heat Transfer Method 5 wherein the heat pipe is a gravity-return-return heat pipe, the operating temperature range of the heat pipe is greater than about 85° C. and wherein said heat sink is at a temperature of from about 15° C. to about 80° C.

The present invention includes Heat Transfer Method 5 wherein the heat pipe is a gravity-return-return heat pipe, the operating temperature range of the heat pipe is greater than about 85° C. and wherein said heat sink is at a temperature of from about 15° C. to about 40° C.

The present invention includes Heat Transfer Method 5 wherein the heat pipe is a gravity-return-return heat pipe, the operating temperature range of the heat pipe greater than about 85° C. and wherein said heat sink is at a temperature of from about 20° C. to about 30° C.

The present invention includes Heat Transfer Method 5 wherein the heat pipe is a gravity-return-return heat pipe and the operating temperature range of the heat pipe is greater than about 88° C.

The present invention includes Heat Transfer Method 5 wherein the heat pipe is a gravity-return-return heat pipe, the operating temperature range of the heat pipe is greater than about 88° C. and wherein said heat sink is at a temperature of from about 15° C. to about 80° C.

The present invention includes Heat Transfer Method 5 wherein the heat pipe is a gravity-return-return heat pipe, the operating temperature range of the heat pipe is greater than about 88° C. and wherein said heat sink is at a temperature of from about 15° C. to about 40° C.

The present invention includes Heat Transfer Method 5 wherein the heat pipe is a gravity-return-return heat pipe, the operating temperature range of the heat pipe greater than about 88° C. and wherein said heat sink is at a temperature of from about 20° C. to about 30° C.

The present invention includes Heat Transfer Method 5 wherein the heat pipe is a gravity-return-return heat pipe and in which the heat pipe operates a heat capacity ratio of 1 or greater. As used herein, heat capacity ratio means the ratio of the heat capacity of the working fluid in the heat pipe compared to the heat capacity of the heat pipe with the working fluid consisting of R-134a.

The present invention includes Heat Transfer Method 5 wherein the heat pipe is a gravity-return-return heat pipe and has a thermal resistance as measured in Example 5 hereof of about 0.5° C. per watt or less.

The present invention includes Heat Transfer Method 6 wherein the operating temperature range of the heat pipe is from about 20° C. to about 100° C.

The present invention includes Heat Transfer Method 6 wherein the heat pipe is a gravity-return-return heat pipe and the operating temperature range of the heat pipe is from about 20° C. to about 100° C.

The present invention includes Heat Transfer Method 6 wherein the heat pipe is a gravity-return-return heat pipe and the operating temperature range of the heat pipe is from about 50° C. to about 100° C.

The present invention includes Heat Transfer Method 6 wherein the heat pipe is a gravity-return-return heat pipe, the operating temperature range of the heat pipe is from about 50° C. to about 100° C. and wherein said heat sink is at a temperature of from about 15° C. to about 80° C.

The present invention includes Heat Transfer Method 6 wherein the heat pipe is a gravity-return-return heat pipe, the operating temperature range of the heat pipe is from about 50° C. to about 100° C. and wherein said heat sink is at a temperature of from about 15° C. to about 40° C.

The present invention includes Heat Transfer Method 6 wherein the heat pipe is a gravity-return-return heat pipe, the operating temperature range of the heat pipe is from about 50° C. to about 100° C. and wherein said heat sink is at a temperature of from about 20° C. to about 30° C.

The present invention includes Heat Transfer Method 6 wherein the heat pipe is a gravity-return-return heat pipe and the operating temperature range of the heat pipe is from about 70° C. to about 100° C.

The present invention includes Heat Transfer Method 6 wherein the heat pipe is a gravity-return-return heat pipe, the operating temperature range of the heat pipe is from about 70° C. to about 100° C. and wherein said heat sink is at a temperature of from about 15° C. to about 80° C.

The present invention includes Heat Transfer Method 6 wherein the heat pipe is a gravity-return-return heat pipe, the operating temperature range of the heat pipe is from about 70° C. to about 100° C. and wherein said heat sink is at a temperature of from about 15° C. to about 40° C.

The present invention includes Heat Transfer Method 6 wherein the heat pipe is a gravity-return-return heat pipe, the operating temperature range of the heat pipe is from about 70° C. to about 100° C. and wherein said heat sink is at a temperature of from about 20° C. to about 30° C.

The present invention includes Heat Transfer Method 6 wherein the heat pipe is a gravity-return-return heat pipe and the operating temperature range of the heat pipe is from about 85° C. to about 95° C.

The present invention includes Heat Transfer Method 6 wherein the heat pipe is a gravity-return-return heat pipe, the operating temperature range of the heat pipe is from about 85° C. to about 100° C. and wherein said heat sink is at a temperature of from about 15° C. to about 80° C.

The present invention includes Heat Transfer Method 6 wherein the heat pipe is a gravity-return-return heat pipe, the operating temperature range of the heat pipe is from about 85° C. to about 100° C. and wherein said heat sink is at a temperature of from about 15° C. to about 40° C.

The present invention includes Heat Transfer Method 6 wherein the heat pipe is a gravity-return-return heat pipe, the operating temperature range of the heat pipe is from about 85° C. to about 100° C. and wherein said heat sink is at a temperature of from about 20° C. to about 30° C.

The present invention includes Heat Transfer Method 6 wherein the heat pipe is a gravity-return-return heat pipe and the operating temperature range of the heat pipe is from about 85° C. to about 95° C.

The present invention includes Heat Transfer Method 6 wherein the heat pipe is a gravity-return-return heat pipe, the operating temperature range of the heat pipe is from about 85° C. to about 95° C. and wherein said heat sink is at a temperature of from about 15° C. to about 80° C.

The present invention includes Heat Transfer Method 6 wherein the heat pipe is a gravity-return-return heat pipe, the operating temperature range of the heat pipe is from about 85° C. to about 95° C. and wherein said heat sink is at a temperature of from about 15° C. to about 40° C.

The present invention includes Heat Transfer Method 6 wherein the heat pipe is a gravity-return-return heat pipe, the operating temperature range of the heat pipe is from about 85° C. to about 95° C. and wherein said heat sink is at a temperature of from about 20° C. to about 30° C.

The present invention includes Heat Transfer Method 6 wherein the heat pipe is a gravity-return-return heat pipe and the operating temperature range of the heat pipe is greater than about 85° C.

The present invention includes Heat Transfer Method 6 wherein the heat pipe is a gravity-return-return heat pipe, the operating temperature range of the heat pipe is greater than about 85° C. and wherein said heat sink is at a temperature of from about 15° C. to about 80° C.

The present invention includes Heat Transfer Method 6 wherein the heat pipe is a gravity-return-return heat pipe, the operating temperature range of the heat pipe is greater than about 85° C. and wherein said heat sink is at a temperature of from about 15° C. to about 40° C.

The present invention includes Heat Transfer Method 6 wherein the heat pipe is a gravity-return-return heat pipe, the operating temperature range of the heat pipe greater than about 85° C. and wherein said heat sink is at a temperature of from about 20° C. to about 30° C.

The present invention includes Heat Transfer Method 6 wherein the heat pipe is a gravity-return-return heat pipe and the operating temperature range of the heat pipe is greater than about 88° C.

The present invention includes Heat Transfer Method 6 wherein the heat pipe is a gravity-return-return heat pipe, the operating temperature range of the heat pipe is greater than about 88° C. and wherein said heat sink is at a temperature of from about 15° C. to about 80° C.

The present invention includes Heat Transfer Method 6 wherein the heat pipe is a gravity-return-return heat pipe, the operating temperature range of the heat pipe is greater than about 88° C. and wherein said heat sink is at a temperature of from about 15° C. to about 40° C.

The present invention includes Heat Transfer Method 6 wherein the heat pipe is a gravity-return-return heat pipe, the operating temperature range of the heat pipe greater than about 88° C. and wherein said heat sink is at a temperature of from about 20° C. to about 30° C.

The present invention includes Heat Transfer Method 7 wherein the heat pipe is a gravity-return-return heat pipe and in which the heat pipe operates a heat capacity ratio of 1 or greater. As used herein, heat capacity ratio means the ratio of the heat capacity of the working fluid in the heat pipe compared to the heat capacity of the heat pipe with the working fluid consisting of R-134a.

The present invention includes Heat Transfer Method 7 wherein the heat pipe is a gravity-return-return heat pipe and has a thermal resistance as measured in Example 5 hereof of about 0.5° C. per watt or less.

The present invention includes Heat Transfer Method 8 wherein the operating temperature range of the heat pipe is from about 20° C. to about 100° C.

The present invention includes Heat Transfer Method 8 wherein the heat pipe is a gravity-return-return heat pipe and the operating temperature range of the heat pipe is from about 20° C. to about 100° C.

The present invention includes Heat Transfer Method 8 wherein the heat pipe is a gravity-return-return heat pipe and the operating temperature range of the heat pipe is from about 50° C. to about 100° C.

The present invention includes Heat Transfer Method 8 wherein the heat pipe is a gravity-return-return heat pipe, the operating temperature range of the heat pipe is from about 50° C. to about 100° C. and wherein said heat sink is at a temperature of from about 15° C. to about 80° C.

The present invention includes Heat Transfer Method 8 wherein the heat pipe is a gravity-return-return heat pipe, the operating temperature range of the heat pipe is from about 50° C. to about 100° C. and wherein said heat sink is at a temperature of from about 15° C. to about 40° C.

The present invention includes Heat Transfer Method 8 wherein the heat pipe is a gravity-return-return heat pipe, the operating temperature range of the heat pipe is from about 50° C. to about 100° C. and wherein said heat sink is at a temperature of from about 20° C. to about 30° C.

The present invention includes Heat Transfer Method 8 wherein the heat pipe is a gravity-return-return heat pipe and the operating temperature range of the heat pipe is from about 70° C. to about 100° C.

The present invention includes Heat Transfer Method 8 wherein the heat pipe is a gravity-return-return heat pipe, the operating temperature range of the heat pipe is from about 70° C. to about 100° C. and wherein said heat sink is at a temperature of from about 15° C. to about 80° C.

The present invention includes Heat Transfer Method 8 wherein the heat pipe is a gravity-return-return heat pipe, the operating temperature range of the heat pipe is from about 70° C. to about 100° C. and wherein said heat sink is at a temperature of from about 15° C. to about 40° C.

The present invention includes Heat Transfer Method 8 wherein the heat pipe is a gravity-return-return heat pipe, the operating temperature range of the heat pipe is from about 70° C. to about 100° C. and wherein said heat sink is at a temperature of from about 20° C. to about 30° C.

The present invention includes Heat Transfer Method 8 wherein the heat pipe is a gravity-return-return heat pipe and the operating temperature range of the heat pipe is from about 85° C. to about 95° C.

The present invention includes Heat Transfer Method 8 wherein the heat pipe is a gravity-return-return heat pipe, the operating temperature range of the heat pipe is from about 85° C. to about 100° C. and wherein said heat sink is at a temperature of from about 15° C. to about 80° C.

The present invention includes Heat Transfer Method 8 wherein the heat pipe is a gravity-return-return heat pipe, the operating temperature range of the heat pipe is from about 85° C. to about 100° C. and wherein said heat sink is at a temperature of from about 15° C. to about 40° C.

The present invention includes Heat Transfer Method 8 wherein the heat pipe is a gravity-return-return heat pipe, the operating temperature range of the heat pipe is from about 85° C. to about 100° C. and wherein said heat sink is at a temperature of from about 20° C. to about 30° C.

The present invention includes Heat Transfer Method 8 wherein the heat pipe is a gravity-return-return heat pipe and the operating temperature range of the heat pipe is from about 85° C. to about 95° C.

The present invention includes Heat Transfer Method 8 wherein the heat pipe is a gravity-return-return heat pipe, the operating temperature range of the heat pipe is from about 85° C. to about 95° C. and wherein said heat sink is at a temperature of from about 15° C. to about 80° C.

The present invention includes Heat Transfer Method 8 wherein the heat pipe is a gravity-return-return heat pipe, the operating temperature range of the heat pipe is from about 85° C. to about 95° C. and wherein said heat sink is at a temperature of from about 15° C. to about 40° C.

The present invention includes Heat Transfer Method 8 wherein the heat pipe is a gravity-return-return heat pipe, the operating temperature range of the heat pipe is from about 85° C. to about 95° C. and wherein said heat sink is at a temperature of from about 20° C. to about 30° C.

The present invention includes Heat Transfer Method 8 wherein the heat pipe is a gravity-return-return heat pipe and the operating temperature range of the heat pipe is greater than about 85° C.

The present invention includes Heat Transfer Method 8 wherein the heat pipe is a gravity-return-return heat pipe, the operating temperature range of the heat pipe is greater than about 85° C. and wherein said heat sink is at a temperature of from about 15° C. to about 80° C.

The present invention includes Heat Transfer Method 8 wherein the heat pipe is a gravity-return-return heat pipe, the operating temperature range of the heat pipe is greater than about 85° C. and wherein said heat sink is at a temperature of from about 15° C. to about 40° C.

The present invention includes Heat Transfer Method 8 wherein the heat pipe is a gravity-return-return heat pipe, the operating temperature range of the heat pipe greater than about 85° C. and wherein said heat sink is at a temperature of from about 20° C. to about 30° C.

The present invention includes Heat Transfer Method 8 wherein the heat pipe is a gravity-return-return heat pipe and the operating temperature range of the heat pipe is greater than about 88° C.

The present invention includes Heat Transfer Method 8 wherein the heat pipe is a gravity-return-return heat pipe, the operating temperature range of the heat pipe is greater than about 88° C. and wherein said heat sink is at a temperature of from about 15° C. to about 80° C.

The present invention includes Heat Transfer Method 8 wherein the heat pipe is a gravity-return-return heat pipe, the operating temperature range of the heat pipe is greater than about 88° C. and wherein said heat sink is at a temperature of from about 15° C. to about 40° C.

The present invention includes Heat Transfer Method 8 wherein the heat pipe is a gravity-return-return heat pipe, the operating temperature range of the heat pipe greater than about 88° C. and wherein said heat sink is at a temperature of from about 20° C. to about 30° C.

The present invention includes Heat Transfer Method 8 wherein the heat pipe is a gravity-return-return heat pipe and in which the heat pipe operates a heat capacity ratio of 1 or greater. As used herein, heat capacity ratio means the ratio of the heat capacity of the working fluid in the heat pipe compared to the heat capacity of the heat pipe with the working fluid consisting of R-134a.

The present invention includes Heat Transfer Method 8 wherein the heat pipe is a gravity-return-return heat pipe and has a thermal resistance as measured in Example 5 hereof of about 0.5° C. per watt or less.

The present invention includes in preferred embodiments methods of transferring heat which comprise: (a) providing a capillary-return heat pipe comprising an evaporating section containing a liquid working fluid comprising greater than 60% by weight of cis 1-chloro-3,3,3-trifluoropropene and a condensing section containing a vaporous working fluid comprising cis 1-chloro-3,3,3-trifluoropropene; (b) placing said evaporating section in thermal communication with a body, fluid, surface or the like to be cooled; (c) placing said condensing section in thermal communication with a body, fluid, surface or the like to be heated; and (d) removing heat from said body, fluid, surface or the like to be cooled by the operation of said heat pipe, wherein the operating temperature range of the capillary-return heat pipe is greater than about 20° C.

The present invention includes Heat Transfer Method 1 wherein the heat pipe is capillary-return heat pipe and the operating temperature range of the heat pipe is from about 20° C. to about 100° C.

The present invention includes Heat Transfer Method 1 wherein the heat pipe is a capillary-return heat pipe heat pipe and the operating temperature range of the heat pipe is from about 50° C. to about 100° C.

The present invention includes Heat Transfer Method 2 wherein the heat pipe is capillary-return heat pipe and the operating temperature range of the heat pipe is from about 20° C. to about 100° C.

The present invention includes Heat Transfer Method 2 wherein the heat pipe is a capillary-return heat pipe heat pipe and the operating temperature range of the heat pipe is from about 50° C. to about 100° C.

The present invention includes Heat Transfer Method 3 wherein the heat pipe is capillary-return heat pipe and the operating temperature range of the heat pipe is from about 20° C. to about 100° C.

The present invention includes Heat Transfer Method 3 wherein the heat pipe is a capillary-return heat pipe heat pipe and the operating temperature range of the heat pipe is from about 50° C. to about 100° C.

The present invention includes Heat Transfer Method 4 wherein the heat pipe is capillary-return heat pipe and the operating temperature range of the heat pipe is from about 20° C. to about 100° C.

The present invention includes Heat Transfer Method 4 wherein the heat pipe is a capillary-return heat pipe heat pipe and the operating temperature range of the heat pipe is from about 50° C. to about 100° C.

The present invention includes Heat Transfer Method 5 wherein the heat pipe is capillary-return heat pipe and the operating temperature range of the heat pipe is from about 20° C. to about 100° C.

The present invention includes Heat Transfer Method 5 wherein the heat pipe is a capillary-return heat pipe heat pipe and the operating temperature range of the heat pipe is from about 50° C. to about 100° C.

The present invention includes Heat Transfer Method 6 wherein the heat pipe is capillary-return heat pipe and the operating temperature range of the heat pipe is from about 20° C. to about 100° C.

The present invention includes Heat Transfer Method 6 wherein the heat pipe is a capillary-return heat pipe heat pipe and the operating temperature range of the heat pipe is from about 50° C. to about 100° C.

The present invention includes Heat Transfer Method 7 wherein the heat pipe is capillary-return heat pipe and the operating temperature range of the heat pipe is from about 20° C. to about 100° C.

The present invention includes Heat Transfer Method 7 wherein the heat pipe is a capillary-return heat pipe heat pipe and the operating temperature range of the heat pipe is from about 50° C. to about 100° C.

The present invention includes Heat Transfer Method 8 wherein the heat pipe is capillary-return heat pipe and the operating temperature range of the heat pipe is from about 20° C. to about 100° C.

The present invention includes Heat Transfer Method 8 wherein the heat pipe is a capillary-return heat pipe heat pipe and the operating temperature range of the heat pipe is from about 50° C. to about 100° C.

The present invention includes in preferred embodiments methods of transferring heat which comprise: (a) providing a heat pipe comprising an evaporating section containing a liquid working fluid comprising greater than 60% by weight of cis 1-chloro-3,3,3-trifluoropropene and a condensing section containing a vaporous working fluid comprising cis 1-chloro-3,3,3-trifluoropropene; (b) placing said evaporating section in thermal communication with a body, fluid, surface or the like to be cooled; (c) placing said condensing section in thermal communication with a body, fluid, surface or the like to which heat can be rejected; and (d) removing heat from said body, fluid, surface or the like to be cooled by the operation of said heat pipe, wherein the power limit of the heat pipe operating at about 50° C. is not degraded by more than 40% relative percent over the operating temperature range of from about 20° C. to about 100° C. and even more preferably by not more than 30% relative percent over the operating temperature range of from about 20° C. to about 100° C. In addition, the method as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

As used herein, the term “power limit” refers to the maximum heat transfer that is possible in the heat pipe without a substantial imbalance in amount of heat transfer occurring in the evaporating and condensing sections, such as might occur, for example, if in a particular application the working fluid encounters capillary limits which do not permit the working fluid condensate to return to the evaporation section at the same rate that vapour is produced in the evaporation section.

The present invention includes in preferred embodiments methods of transferring heat which comprise: (a) providing a gravity-return return heat pipe comprising an evaporating section containing a liquid working fluid comprising greater than 60% by weight of cis 1-chloro-3,3,3-trifluoropropene and a condensing section containing a vaporous working fluid comprising cis 1-chloro-3,3,3-trifluoropropene; (b) placing said evaporating section in thermal communication with a body, fluid, surface or the like to be cooled; (c) placing said condensing section in thermal communication with a body, fluid, surface or the like to which heat can be rejected; and (d) removing heat from said body, fluid, surface or the like to be cooled by the operation of said heat pipe, wherein the power limit of the heat pipe operating at about 50° C. is not degraded by more than 15% relative percent over the operating temperature range of from about 50° C. to about 100° C., and even more preferably by not more than 10% relative percent over the operating temperature range of from about 50° C. to about 100° C. In addition, the method as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

As discussed in more detail below, applicants have found that the methods, heat pipes, electronic devices, electronic components, systems and compositions as described herein are unexpectedly able to achieve high levels of operational effectiveness and efficiency in both capillary-return and gravity-return-return heat pipes. One measure of the effectiveness of heat pipe operation, particularly for those methods and systems involving the cooling of small electronic components, is the ability of the heat pipe to provided high levels of cooling once the heat load is applied, that is, the electronic component is turned on, and preferably in some embodiments at a relatively rapid rate. Another measure of the effectiveness of heat pipe operation, particularly for those methods and systems involving the cooling of small electronic components, is the ability to achieve the required level of cooling while maintaining a relatively small temperature differential (e.g., less than 5° C.) between the evaporator section and the condenser section of the heat pipe. Another measure of the effectiveness of heat pipe operation, particularly for those methods and systems involving the cooling of small electronic components, is the ability to achieve the required level of cooling while maintaining a temperature differential between the evaporator section and the heat sink that is as low as, or lower than, such temperature differential if heat pipe were operated with R-134a as the working fluid. Applicants have found that the methods, systems, device, components and compositions of the present invention in preferred embodiments are able to provide highly desirable and unexpectedly excellent performance with regard to one or more of these criteria.

The present invention includes in preferred embodiments methods of transferring heat which comprise: (a) providing a heat pipe comprising an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene; (b) placing said evaporating section in thermal communication with a body, fluid, surface or the like to be cooled; (c) placing said condensing section in thermal communication with a body, fluid, surface or the like to be heated; and (d) removing heat from said body, fluid, surface or the like to be cooled by the operation of said heat pipe, wherein the heat pipe performance as measured by temperature differential between the evaporator section and the condenser section is equal to or better than the performance of R-134a in the same heat pipe. In addition, the method as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention includes in preferred embodiments methods of transferring heat which comprise: (a) providing a heat pipe comprising an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene; (b) placing said evaporating section in thermal communication with a body, fluid, surface or the like to be cooled; (c) placing said condensing section in thermal communication with a body, fluid, surface or the like to be heated; and (d) removing heat from said body, fluid, surface or the like to be cooled by the operation of said heat pipe, wherein the heat pipe performance as measured by temperature differential between the evaporator section and the condenser section is equal to or better than the performance of R-134a in the same heat pipe. In addition, the method as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention includes in preferred embodiments methods of transferring heat which comprise: (a) providing a heat pipe comprising an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene; (b) placing said evaporating section in thermal communication with a body, fluid, surface or the like to be cooled; (c) placing said condensing section in thermal communication with a body, fluid, surface or the like to be heated; and (d) removing heat from said body, fluid, surface or the like to be cooled by the operation of said heat pipe, wherein the operating temperature range of the heat pipe is from about −20° C. to about 200° C. In addition, the method as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention includes in preferred embodiments methods of transferring heat which comprise: (a) providing a heat pipe comprising an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene; (b) placing said evaporating section in thermal communication with a body, fluid, surface or the like to be cooled; (c) placing said condensing section in thermal communication with a body, fluid, surface or the like to be heated; and (d) removing heat from said body, fluid, surface or the like to be cooled by the operation of said heat pipe, wherein the operating temperature range of the heat pipe is from about −0° C. to about 140° C. In addition, the method as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention includes in preferred embodiments methods of transferring heat which comprise: (a) providing a heat pipe comprising an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene; (b) placing said evaporating section in thermal communication with a body, fluid, surface or the like to be cooled; (c) placing said condensing section in thermal communication with a body, fluid, surface or the like to be heated; and (d) removing heat from said body, fluid, surface or the like to be cooled by the operation of said heat pipe, wherein the operating temperature range of the heat pipe is from about 20° C. to about 140° C. In addition, the method as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention includes in preferred embodiments methods of transferring heat which comprise: (a) providing a heat pipe comprising an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene; (b) placing said evaporating section in thermal communication with a body, fluid, surface or the like to be cooled; (c) placing said condensing section in thermal communication with a body, fluid, surface or the like to be heated; and (d) removing heat from said body, fluid, surface or the like to be cooled by the operation of said heat pipe, wherein the operating temperature range of the heat pipe is from about 40° C. to about 140° C. In addition, the method as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention includes a method of cooling an article using a heat pipe, wherein said heat pipe contains a heat transfer composition as previously defined and the heat pipe is a capillary return heat pipe, a gravity-return return heat pipe, a centripetal force return heat pipe, an oscillating heat pipe, an osmotic force return heat pipe, an electrokinetic force return heat pipe or a magnetic force return heat pipe.

Preferably the heat pipe is a capillary return or a gravity-return return heat pipe.

The method of the invention particularly includes the cooling of an electric or electronic component. The method particularly relates to the cooling of an electric device, an e-vehicle, a data centre or a light emitting diode (LED), or in the heat management of a spacecraft or in heat recovery.

Where the method relates to the cooling of an electric device, the method particularly includes the cooling of an insulated gate bipolar transistor (IGBT), projector, or games console computer.

Where the method relates to the cooling of an e-vehicle, the method particularly includes the cooling of a battery, motor or power control unit (PCU) in an e-vehicle.

Where the method relates to the cooling of a data centre, the method particularly includes to the cooling of a central processing unit (CPU), graphic processing unit (GPU), memory, blade or Rack.

Where the method relates to the cooling of a light emitting diode (LED), the method particularly includes to the cooling of a light emitting diode (LED) light or quantum dot light emitting diode (QLED) TV, an organic light emitting diode (OLED) or other displays using heat pipes to enhance heat dissipation.

Where the method relates to the heat management of a spacecraft, particularly a military or commercial spacecraft, the method particularly includes the heat management of a radar, a laser, satellite or space station.

Where the method relates to heat recovery, the method particularly includes data center heat recovery between hot fresh air and cold inner air.

Where the method relates to cooling a communication device, the method particularly includes cooling radio frequency (RF) chips, cooling WiFi systems, cooling base station cooling, cooling mobile phones or cooling switchs.

Where the method relates to refrigeration and/or freezer applications, the method particularly includes defrosting, making ice, enhancing the uniformity of air temperature for example in a refrigeration compartment.

### Electronic Components

As mentioned above, the present invention relates in particular embodiments to electronic components, which are advantageously cooled by a heat pipe of the present invention. Accordingly, the present invention includes in preferred embodiments electronic devices that include components that operate at temperatures above ambient comprising: (a) an electronic component that in operation generates heat and raises the temperature of said component to above ambient; and (b) a heat pipe comprising an evaporating section containing a liquid working fluid comprising greater than 60% by weight of cis 1-chloro-3,3,3-trifluoropropene and a condensing section containing a vaporous working fluid comprising cis 1-chloro-3,3,3-trifluoropropene, wherein said evaporating section is thermally connected to said electronic component and wherein said condenser section is thermally connected to a heat sink, wherein said heat sink is at a temperature of from about 20° C. to about 100° C., more preferably at a temperature from about 50° C. to about 100° C., In addition, the electronic device as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention includes in preferred embodiments electronic devices that include components that operate at temperatures above ambient comprising: (a) an electronic component that in operation generates heat and raises the temperature of said component to above ambient; and (b) a heat pipe comprising an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene, wherein said evaporating section is thermally connected to said electronic component and wherein said condenser section is thermally connected to a heat sink, wherein said heat sink is at a temperature of from about 20° C. to about 100° C., more preferably at a temperature from about 50° C. to about 100° C. and, wherein the operating temperature range of the heat pipe is from about 20° C. to about 100° C. In addition, the electronic device as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention includes in preferred embodiments electronic devices that include components that operate at temperatures above ambient comprising: (a) an electronic component that in operation generates heat and raises the temperature of said component to above ambient; and (b) a capillary-return heat pipe comprising an evaporating section containing a liquid working fluid comprising greater than 60% by weight of cis 1-chloro-3,3,3-trifluoropropene and a condensing section containing a vaporous working fluid comprising cis 1-chloro-3,3,3-trifluoropropene, wherein said evaporating section is thermally connected to said electronic component and wherein said condenser section is thermally connected to a heat sink, wherein said heat sink is at a temperature of from about 20° C. to about 100° C., more preferably at a temperature from about 50° C. to about 100° C., wherein the operating temperature range of the capillary-return heat pipe is greater than about 20° C. In addition, the electronic device as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention includes in preferred embodiments electronic devices that include components that operate at temperatures above ambient comprising: (a) an electronic component that in operation generates heat and raises the temperature of said component to above ambient; and (b) a capillary-return heat pipe comprising an evaporating section containing a liquid working fluid comprising greater than 60% by weight of cis 1-chloro-3,3,3-trifluoropropene and a condensing section containing a vaporous working fluid comprising cis 1-chloro-3,3,3-trifluoropropene, wherein said evaporating section is thermally connected to said electronic component and wherein said condenser section is thermally connected to a heat sink, wherein said heat sink is at a temperature of from about 20° C. to about 100° C., more preferably at a temperature from about 50° C. to about 100° C., wherein the operating temperature range of the capillary-return heat pipe is from about 20° C. to about 100° C. In addition, the electronic device as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention includes in preferred embodiments electronic devices that include components that operate at temperatures above ambient comprising: (a) an electronic component that in operation generates heat and raises the temperature of said component to above ambient; and (b) a gravity-return-return heat pipe comprising an evaporating section containing a liquid working fluid comprising greater than 60% by weight of cis 1-chloro-3,3,3-trifluoropropene and a condensing section containing a vaporous working fluid comprising cis 1-chloro-3,3,3-trifluoropropene, wherein said evaporating section is thermally connected to said electronic component and wherein said condenser section is thermally connected to a heat sink, wherein said heat sink is at a temperature of from about 20° C. to about 100° C., more preferably at a temperature from about 50° C. to about 100° C. and, wherein the operating temperature range of the gravity-return-return heat pipe is greater than about 40° C. In addition, the electronic device as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention includes in preferred embodiments electronic devices that include components that operate at temperatures above ambient comprising: (a) an electronic component that in operation generates heat and raises the temperature of said component to above ambient; and (b) a gravity-return-return heat pipe comprising an evaporating section containing a liquid working fluid comprising greater than 60% by weight of cis 1-chloro-3,3,3-trifluoropropene and a condensing section containing a vaporous working fluid comprising cis 1-chloro-3,3,3-trifluoropropene, wherein said evaporating section is thermally connected to said electronic component and wherein said condenser section is thermally connected to a heat sink, wherein said heat sink is at a temperature of from about 20° C. to about 100° C., more preferably at a temperature from about 50° C. to about 100° C., wherein the operating temperature range of the gravity-return-return heat pipe is from about 40° C. to about 100° C. In addition, the electronic device as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention includes electronic devices comprising an electronic component and a heat pipe of the present invention thermally connected to the device to cool the device in operation. As used herein, the term “electronic devices” means any device which operates by or which generates the flow of electricity. Thus, a preferred embodiment of the present invention includes an insulated gate bipolar transistor (IGBT) that in operation generates heat causing an increase in its temperature to above ambient; and (b) a heat pipe, preferably a capillary-return heat pipe or a gravity-return return heat pipe or a capillary/gravity-return return heat pipe, comprising an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene, wherein said evaporating section is thermally connected to said IGBT and wherein said condenser section is thermally connected to a heat sink at a temperature less than the temperature of said IGBT, wherein the operating temperature range of the heat pipe is from about 20° C. to about 100° C. In addition, the IGBT as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

A preferred embodiment of the present invention includes a projector comprising at least one electronic component that in operation generates heat causing an increase in its temperature to above ambient; and (b) a heat pipe, preferably a capillary-return heat pipe or a gravity-return return heat pipe or a capillary/gravity-return return heat pipe, comprising an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene, wherein said evaporating section is thermally connected to said at least one electronic component and wherein said condenser section is thermally connected to a heat sink at a temperature less than the temperature of said at least one electronic component, wherein the operating temperature range of the heat pipe is from about 20° C. to about 100° C. In addition, the projector as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene,

A preferred embodiment of the present invention includes a games console computer comprising at least one electronic component that in operation generates heat causing an increase in its temperature to above ambient; and (b) a heat pipe, preferably a capillary-return heat pipe or a gravity-return return heat pipe or a capillary/gravity-return return heat pipe, comprising an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene, wherein said evaporating section is thermally connected to said at least one electronic component and wherein said condenser section is thermally connected to a heat sink at a temperature less than the temperature of said at least one electronic component, wherein the operating temperature range of the heat pipe is from about 20° C. to about 100° C. In addition, the games console computer as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

A preferred embodiment of the present invention includes an E-Vehicle that comprises at least one electronic component, said electronic component preferably selected from a battery, motor or power control unit (PCU), that in operation generates heat causing an increase in its temperature to above ambient; and (b) a heat pipe, preferably a capillary-return heat pipe or a gravity-return return heat pipe or a capillary/gravity-return return heat pipe, comprising an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene, wherein said evaporating section is thermally connected to said at least one electronic component and wherein said condenser section is thermally connected to a heat sink at a temperature less than the temperature of said at least one electronic component, wherein the operating temperature range of the heat pipe is from about 20° C. to about 100° C. In addition, the games console computer as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

A preferred embodiment of the present invention includes an electronic component of a ata center, said electronic component preferably comprising a central processing unit (CPU), graphic processing unit (GPU), memory, blade or Rack, and combinations of these, that in operation generates heat causing an increase in its temperature to above ambient; and (b) a heat pipe, preferably a capillary-return heat pipe or a gravity-return return heat pipe or a capillary/gravity-return return heat pipe, comprising an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene, wherein said evaporating section is thermally connected to said electronic component and wherein said condenser section is thermally connected to a heat sink at a temperature less than the temperature of said at least one electronic component, wherein the operating temperature range of the heat pipe is from about 20° C. to about 100° C. In addition, the electronic component as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

A preferred embodiment of the present invention includes an electronic component of a display device, such as a televisions, computer display, and the like, said electronic component preferably selected from a light emitting diode (LED), quantum dot light emitting diode (QLED), organic light emitting diode (OLED) that in operation generates heat causing an increase in its temperature to above ambient; and (b) a heat pipe, preferably a capillary-return heat pipe or a gravity-return return heat pipe or a capillary/gravity-return return heat pipe, comprising an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene, wherein said evaporating section is thermally connected to said electronic component and wherein said condenser section is thermally connected to a heat sink at a temperature less than the temperature of said at least one electronic component, wherein the operating temperature range of the heat pipe is from about 20° C. to about 100° C. In addition, the electronic component as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene; In preferred embodiments, the present methods, systems, heat pipes and compositions are used in connection with:
Spacecraft device heat management, particularly military or commercial spacecraft, particularly the heat management, more particularly the cooling of a radar, laser, satellite or space station;
Heat recovery, particularly heat recovery from a data center, wherein the heat recovery is between hot fresh air and cold inner air;
Communication device cooling particularly the cooling of a radio frequency (RF) chip, WiFi system, base station cooling, mobile phone or a switch;

Refrigeration and/or freezer applications, such as defrosting, making ice, enhancing and/or maintaining the uniformity of air temperature for example in a compartment of a refrigerator.

### Heat Pipes

The present invention includes heat pipes that comprise an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene. In addition, the heat pipe as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

In preferred embodiments, the evaporating section and the condensing section of any of the heat pipes described herein are different portions of a sealed container, with the working fluid of the present invention being permanently sealed into the container. As used herein, the term container refers to a vessel or combination of vessels, conduits and the like which allow for liquid and vapour to travel between the evaporating section and the condensing section as described herein. Furthermore, the vessel may include various fins and the like known to those skilled in the art to enhance thermal communication between the evaporating section and the item, surface or body to be cooled and/or to enhance thermal communication between the condensing section and the item, surface, body into which the heat will be rejected, that is, the heat sink.

The present invention provides in preferred embodiments a a gravity-return return heat pipe that comprise an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene. In addition, the heat pipe as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention provides in preferred embodiments a capillary return heat pipe that comprises an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene. In addition, the method as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

The present invention provides in preferred embodiments, a capillary/gravity-return return heat pipe that comprises an evaporating section containing a liquid working fluid comprising at least about 60% by weight of cis 1-chloro-3,3,3-trifluoropropene and a condensing section containing a vaporous working fluid comprising at least about 60% by weight of cis 1-chloro-3,3,3-trifluoropropene. As used herein, the term “capillary/gravity-return return” heat pipe means a heat pipe in which liquid working fluid returns to the evaporating section as a result of at least gravitational and capillary forces. An embodiment of the present invention includes a capillary/gravity-return return heat pipe in which liquid working fluid returns to the evaporating section as a result of only gravitational and capillary forces. In addition, the heat pipes as described in this paragraph in preferred embodiments is the same as described except the liquid working fluid and the vapour working fluid each comprise at least about 70% by weight, or at least about 80% by weight, or at least about 90% by weight, or at least about 95% by weight, or at least about 97% by weight, or at least about 99.5% by weight, or consists essentially of, or consists of, cis 1-chloro-3,3,3-trifluoropropene.

For the purposes of this invention, the composition comprising, consisting essentially of or consisting of cis 1-chloro-3,3,3-trifluoropropene can also be provided for use in, a centripetal driven heat pipe (or rotating heat pipe), an electrokinetic driven heat pipe (electrohydrodynamic heat pipe and electro-osmotic heat pipe), a magnetic driven heat pipe, an oscillating heat pipe or an osmotic heat pipe, and any combinations of these with one another and/or with a gravity-return return heat pipe, a capillary return heat pipe and/or a gravity-return/capillary return heat pipe.

In preferred embodiments the present invention comprises a heat pipe comprises a closed container containing a working fluid comprising at least about 60% by weight of cis 1-chloro-3,3,3-trifluoropropene, said closed container having at least one wall for transferring heat to and/or from the working fluid, said at least one wall having a thickness of less than about 0.065 mm, and even more preferably from less than about 0.05 mm to about 0.002 mm, where said container is cylindrical and has an outer diameter of about 5 mm. Such heat pipes according to these preferred embodiments are advantageous because such a thin wall allows a reduction in the heat pipe thermal resistance and have other commercial and environmental benefits.

One measure of heat pipe performance can be measured by thermal resistance, which is defined by the following formula:

R=(Twe-Twc)/Q according to Standard GB/T 14812-2008.

### Where,

Twc is average temperature of heat pipe condensing part, according to Standard GB/T 14812-2008, ° C.;
Twe is average temperature of heat pipe evaporating part, according to Standard GB/T 14812-2008, ° C.;
Q is heat pipe heat transfer capacity, according to Standard GB/T 14812-2008,

Applicants have found that exception heat pipe performance, including as measure by thermal resistance, is achieved according to the preferred embodiments of the present invention.

Another measure that can be used to estimate the ability of a particular working fluid to operate effectively in a heat pipe for a selected operating temperature is called the Merit Number (as described in more detail hereinafter), which is a number that reflects the effect the working fluid will have on the heat pipe performance, including the estimated maximum power transfer for the given operating temperature. Specifically, the amount of power that a heat pipe can carry is governed by the lowest heat pipe limit at a given temperature. The Merit number can be used to estimate the maximum heat pipe power when the heat pipe is capillary limited for the capillary return heat pipe. The capillary limit is reached when the sum of the liquid, vapor, and gravitational pressure drops is equal to the capillary pumping capability. The Merit number neglects the vapor and gravitational pressure drops, and assumes that the capillary pumping capability is equal to liquid pressure drop, to reflect working fluid performance limit inside heat pipe. Nevertheless, applicants have used the data it has generated experimentally regarding the properties of cis 1-chloro-3,3,3-trifluoropropene to determine Merit number for various operating temperatures selected by applicant, to provide confirmation of the unexpected result achieved according to the present invention.

Applicants have found that for heat pipe operation with an operating temperature range of greater than about 40° C., and preferably from about 40° C. to about 100° C., a heat-pipe according to the present invention that has only gravity-return return (e.g. no capillary action) has a Merit Number which is equal to or higher than that of R134a. Furthermore, applicants have also surprisingly found that for heat pipe operation with an operating temperature range of greater than about 20° C., and preferably from about 20° C. to about 100° C., a heat-pipe according to the present invention that has only capillary return (e.g. no gravity-return contribution) has a Merit Number which is equal to or higher than that of R134a. The specifics of these unexpected results are explained in further detail hereinafter. Another advantage achieved according to the preferred methods, apparatus and compositions of the present invention is the ability for the heat pipe to operate effectively at a lower inner pressure compared with R134a, which in turn allows the use of relatively thinner heat pipe walls and enhances heat pipe total thermal conductivity.

The invention further relates to a heat pipe containing a working fluid, where said working fluid comprises at least about 60% by weight of cis 1-chloro-3,3,3-trifluoropropene.

The invention relates to a heat pipe containing a working fluid, where said working fluid comprises at least about 70% by weight of cis 1-chloro-3,3,3-trifluoropropene.

The invention relates to a heat pipe containing a working fluid, where said working fluid comprises at least about 80% by weight of cis 1-chloro-3,3,3-trifluoropropene.

The invention relates to a heat pipe containing a working fluid, where said working fluid comprises at least about 90% by weight of cis 1-chloro-3,3,3-trifluoropropene.

The invention relates to a heat pipe containing a working fluid, where said working fluid comprises at least about 95% by weight of cis 1-chloro-3,3,3-trifluoropropene.

The invention relates to a heat pipe containing a working fluid, where said working fluid comprises at least about 97% by weight of cis 1-chloro-3,3,3-trifluoropropene.

The invention relates to a heat pipe containing a working fluid, where said working fluid comprises at least about 99.5% by weight of cis 1-chloro-3,3,3-trifluoropropene.

The invention relates to a heat pipe containing a working fluid, where said working fluid consists essentially of cis 1-chloro-3,3,3-trifluoropropene.

The invention relates to a heat pipe containing a working fluid, where said working fluid consists of cis 1-chloro-3,3,3-trifluoropropene.

The heat pipe is selected from a capillary return heat pipe, a gravity-return return heat pipe, a centripetal force return heat pipe, an oscillating heat pipe, an osmotic force return heat pipe, an electrokinetic force return heat pipe or a magnetic force return heat pipe.

The heat pipe is preferably a capillary return or gravity-return return heat pipe.

### Working Fluid Compositions

The present invention includes the use of a composition comprising at least about 60% by weight of cis 1-chloro-3,3,3-trifluoropropene, as a working fluid in a heat pipe.

The invention further includes the use of a composition comprising at least about 70% by weight of cis 1-chloro-3,3,3-trifluoropropene, as a working fluid in a heat pipe.

The invention further includes the use of a composition comprising at least about 80% by weight of cis 1-chloro-3,3,3-trifluoropropene, as a working fluid in a heat pipe.

The invention further includes the use of a composition comprising at least about 90% by weight of cis 1-chloro-3,3,3-trifluoropropene, as a working fluid in a heat pipe.

The invention further includes the use of a composition comprising at least about 95% by weight of cis 1-chloro-3,3,3-trifluoropropene, as a working fluid in a heat pipe.

The invention further includes the use of a composition comprising at least about 97% by weight of cis 1-chloro-3,3,3-trifluoropropene, as a working fluid in a heat pipe.

The invention further includes the use of a composition comprising at least about 99.5% by weight of cis 1-chloro-3,3,3-trifluoropropene, as a working fluid in a heat pipe.

The invention further includes the use of a composition consisting essentially of cis 1-chloro-3,3,3-trifluoropropene, as a working fluid in a heat pipe.

The invention further relates to the use of a composition consisting of cis 1-chloro-3,3,3-trifluoropropene, as a working fluid in a heat pipe.

### Electronic Devices

### The Working Fluid

The present invention thus provides a working fluid for heat pipes, and in particular for gravity-return return heat pipes, capillary return heat pipes and gravity-return/capillary return heat pipes, comprising at least about 60% by weight of cis 1-chloro-3,3,3-trifluoropropene. Cis 1-chloro-3,3,3-trifluoropropene is a known compound and can be produced according to one or more of several known methods, including but not limited to the method disclosed in US 2014/0275644, assigned to the assignee of the present application.

Thus, the composition of the present invention is particularly provided for use in those applications which require a working temperature above about 100° C., such applications including cooling of an insulated gate bipolar transistor (IGBT), a projector, a motor, a power control unit (PCU), a light emitting diode (LED) light, a quantum dot light emitting diode (QLED), or in communication device cooling such as a radio frequency (RF) chip, WiFi system, base station cooling, mobile phone or a switch or in heat management in a space craft device, for example of a radar, a satellite or space station.

A composition comprising cis 1-chloro-3,3,3-trifluoropropene of the invention is particularly favoured for use in a capillary return heat pipe as:
The Merit number of cis 1-chloro-3,3,3-trifluoropropene is higher than that of R134a at a temperature greater than about 20° C., for example the Merit number of cis 1-chloro-3,3,3-trifluoropropene is at least about 65% higher than the Merit number of R134a at about 50° C.
Cis 1-chloro-3,3,3-trifluoropropene demonstrates a lower inner pressure than R134a allowing the use of a thin heat pipe wall. In particular, at about 50° C., R134a will require a minimum wall thickness of about 0.065 mm, while cis 1-chloro-3,3,3-trifluoropropene will require a minimum wall thickness of about 0.002 mm for a pipe with an outer diameter of about 5 mm. This allows a reduction in the heat pipe thermal resistance. In addition, the heat pipes can be produced using less metal, which provides both commercial and environmental benefits.
The Merit number of cis 1-chloro-3,3,3-trifluoropropene is consistent between a working temperature of about 40° C. and about 140° C. allowing its use in applications having a working temperature above about 100° C. For example, when the working temperature changes from about 40° C. to about 80° C., the Merit number of R134a will degrade by about 75% compared with about 5% for cis 1-chloro-3,3,3-trifluoropropene.

The present invention therefore provides the use of a composition comprising at least about 95% by weight of 1-chloro-3,3,3-trifluoropropene, wherein said 1-chloro-3,3,3-trifluoropropene is at least about 90 wt % cis 1-chloro-3,3,3-trifluoropropene in a capillary return heat pipe, wherein the working temperature of the heat pipe is from about −20° C. to about 200° C.

The present invention further provides the use of a composition as defined above in a capillary return heat pipe, wherein the working temperature of the heat pipe is from about 0° C. to about 140° C., preferably from about 20° C. to about 140° C., or from about 40° C. to about 80° C.

A composition comprising cis 1-chloro-3,3,3-trifluoropropene of the invention is particularly favoured for use in a gravity-return return heat pipe as:
The Merit number of cis 1-chloro-3,3,3-trifluoropropene is higher than that of R134a at a temperature greater than about 40° C. For example, the Merit number of cis 1-chloro-3,3,3-trifluoropropene is about 22% higher than R134a at about 80° C.
Cis 1-chloro-3,3,3-trifluoropropene demonstrates a lower inner pressure than R134a allowing the use of a thin heat pipe wall. In particular, at about 50° C., R134a will require a minimum wall thickness of about 0.065 mm, while cis 1-chloro-3,3,3-trifluoropropene will require a minimum wall thickness of about 0.002 mm for a pipe with an outer diameter of about 5 mm. This allows a reduction in the heat pipe thermal resistance. In addition, the heat pipes can be produced using less metal, which provides both commercial and environmental benefits.
The Merit number of cis 1-chloro-3,3,3-trifluoropropene is consistent between a working temperature of about 40° C. and about 140° C. allowing its use in applications having a working temperature above about 100° C. For example, when the working temperature changes from about 40° C. to about 80° C., the Merit number of R134a will degrade by about 23% compared with about 6% for cis 1-chloro-3,3,3-trifluoropropene.

The present invention therefore provides the use of a composition comprising at least about 95% by weight of 1-chloro-3,3,3-trifluoropropene, wherein said 1-chloro-3,3,3-trifluoropropene is at least about 90 wt % cis 1-chloro-3,3,3-trifluoropropene in a gravity-return return heat pipe, wherein the working temperature of the heat pipe is from about −20° C. to about 200° C.

The present invention further provides the use of a composition as defined above in a gravity-return return heat pipe, wherein the working temperature of the heat pipe is from about 0° C. to about 140° C., preferably from about 20° C. to about 140° C., or from about 40° C. to about 80° C.

Preferably, the working fluid of the present invention has a Global Warming Potential (GWP) of not greater than about 1000, more preferably not greater than about 750, more preferably not greater than about 500 and even more preferably not greater than about 150. As used herein “GWP” is measured relative to that of carbon dioxide and over a 100 year time horizon as defined in “The Scientific Assessment of Ozone Depletion, 2002, a report of the World Meteorological Association's Global Ozone Research and Monitoring Project”, which is incorporated herein by reference.

Preferably, the working fluid of the present invention also preferably has an Ozone Depletion Potential (ODP) of not greater than about 0.05, more preferably not greater than about 0.02, even more preferably about zero. As used herein, “ODP” is defined in “The Scientific Assessment of Ozone Depletion, 2002, A report of the World Meteorological Association's Global Ozone Research and Monitoring Project” which is incorporated herein by reference.

### Method of Preparing a Heat Pipe

The invention further relates to a process of preparing a heat pipe containing a working fluid of the present invention, wherein said working fluid is as previously defined, wherein the method comprises adding to the heat pipe the working fluid

Preferably, any contents of the heat pipe are removed under vacuum, prior to prior to the adding step. Alternatively, the working fluid can be added to the heat pipe and then heated to remove air from the heat pipe.

The adding step preferably comprises adding the working fluid to the heat pipe until the design weight of working fluid is contained in the heat pipe. Although it is contemplated that the amount of working fluid can vary widely depending on the particular heat pipe design, the particular body to be cooled, expected ambient conditions, among others, preferably for embodiments involving the cooling of electronic equipment, the working fluid is present in the heat pipe in an amount of from about 1 to about 2000 grams. Alternatively, for embodiments involving the cooling of electronic equipment, including electronic communications systems such as WiFi systems, the working fluid is present in the heat pipe in an amount of from about 2 to about 500, grams, or from about 2 to about 100 grams, from about 10 to about 80 grams from about 20 to about 60 grams or from about 30 to about 50 grams. The heat pipe is then preferably sealed. The heat pipe can be sealed, for example, by soldering or pressure extruding.

The present invention will now be illustrated by reference to the following non-limiting examples:

### EXAMPLES

### Comparative Example 1—Capillary Heat Pipe with R-134a as Working Fluid at 50° C.

A capillary heat pipe with a working fluid consisting essentially of HFC-134a and which has no substantial gravity-return assist for return of the liquid phase working fluid from the condenser to the evaporator is evaluated at an operating temperature of 50° C. The required parameters, i.e. liquid fluid density, liquid fluid conductivity, liquid fluid viscosity and fluid latent heat are taken at a specified temperature, with the assumption that temperature differences along the heat pipe are negligible as described by D. A. Reay, P. A. Kew, R. J. McGlen, Heat Pipes Theory, Design and Applications, Sixth edition, UK: Elsevier, 2014. Published and publically available information for R-134a is used and particular information for the operating temperature, to the extent it is required, is estimated using Refprop 9.1, (https://www.nist.gov/refprop), developed by NIST (National Institute of Standards and Technology, USA).

The working pressure for this configuration with R-134a as the working fluid were determined to be 1317.9 KPa, as determined by Refprop 9.1.

Based on the working pressure, the Minimum wall thickness is estimated using Standard ASME B31.3, as follows:

$$t = \frac{PD}{2 SE + 2 yP} + C$$

### Where,

t is minimum wall thickness required, inches;
P is design pressure, Psig; equal to working fluid 50° C. saturation pressure in this calculation;
D is outside diameter of pipe, inches;
S is allowable stress in pipe material, Psi, equal to 6700 psi from aluminium alloy 3003 in Table A-1 of ASME B31.3B;
E is joint factor, equal to 1.0 for seamless pipe;
C is corrosion allowance, equal to 0 in this calculation;
Y is wall thickness coefficient in ASME B31.3 Table 304.1.1; equal to 0.4 in this calculation.

This shows that at an operating temperature of 50° C., R134a requires a minimum wall thickness of about 0.065 mm for a pipe diameter of 5 mm.

### Example 1—Capillary Heat Pipe with cis1233zd as Working Fluid at 50° C.

Comparative Example 1 is repeated, except that the working fluid consists of cis1233zd, and except that some of the physical property values for cis1233zd determined experimentally by the applicants.

The working pressure for this configuration was determined to be 140.8 KPa, which is an order of magnitude less than the working pressure for R-134a. These results demonstrate one significant advantage according to the present invention, particularly that the heat pipe the present invention has the advantage, because of the low working pressure, of a minimum wall thickness of about 0.002 mm for a pipe diameter of 5 mm. In addition, the Merit number for each of Comparative Example 1 and this Example 1 was determined according to the the equation set out below, in accordance with D. A. Reay, P. A. Kew, R. J. McGlen, Heat Pipes Theory, Design and Applications, Sixth edition, UK: Elsevier, 2014.

$$M = \frac{{ρ}_{f} {σ}_{f} γ}{{μ}_{f}}$$

### Where,

M is Merit Number for capillary return heat pipe;
ρ_{f} is liquid working fluid density, kg/m³;
σ_{f} is liquid working fluid surface tension, N/m;
μ_{f} is liquid working fluid viscosity, Pa S;
γ is fluid working latent heat, J/kg.

The Merit number for this Example 1 is determined to be 169% greater than the Merit number of Comparative Example 1, thus providing further evidence of advantageous and unexpected results achieved according to the present invention.

### Comparative Example 2—Power Limit Degradation for Heat Pipes with R-134a

In order to estimate the power limit degradation of a capillary heat pipe in which the working fluid consists of R-134a, the Merit number has been determined for operating temperatures ranging from about 20° C. to about 100° C. using the same process as described in connection with Comparative Example 1, and these determinations are reported in Table C2 below based on the power limit at 50° C. being the baseline from which the relative power limit at each temperature is reported:

TABLE C2

| | Power Limit Estimate, % |
|---|---|
| Operating Temp (° C.) | of Power Limit at 50° C. |
| 20 | 163% |
| 30 | 144% |
| 40 | 123% |
| 50 | 100% |
| 60 | 76% |
| 70 | 53% |
| 80 | 31% |
| 90 | 12% |
| 100 | 0.3% |

As can be seen from the table above, the power limit of a capillary heat pipe with working fluid consisting of R-134a is estimated to experience a rapid deterioration, on the order of 100% deterioration, as the operating temperature reaches about 100° C. For the reasons explained elsewhere herein, an possibly others, applicants have come to appreciate and expect based on this work that R-134a is likely to have disadvantages when the operating temperature for the heat pipe includes the range from about 20° C. to about 100° C., and especially in the range from 50° C. to about 100° C.

### Example 2—Power Limit Degradation for Capillary Heat Pipes with cis1233zd

In order to estimate the power limit degradation of a capillary heat pipe in which the working fluid consists of cis1233zd, the Merit number has been determined for operating temperatures ranging from about 0° C. to about 120° C. using the same process as described in connection with Comparative Example 2, and these determinations are reported in Table E2 below based on the power limit at 50° C. being the baseline from which the relative power limit at each temperature is reported:

TABLE E2

| | Power Limit Estimate, % |
|---|---|
| Operating Temp (° C.) | of Power Limit at 50° C. |
| 20 | 96% |
| 30 | 98% |
| 40 | 100% |
| 50 | 100% |
| 60 | 99% |
| 70 | 98% |
| 80 | 95% |
| 90 | 92% |
| 100 | 87% |
| 110 | 82% |
| 120 | 76% |
| 130 | 70% |
| 140 | 62% |
| 150 | 54% |

As can be seen from the table above, and based on applicants' experimental work and analysis, the power limit of a capillary heat pipe with working fluid consisting of cis1233zd produces a power limit profile that is dramatically and advantageously much more stable that that exhibited by R-134a in the operating temperature range from 20° C. to 100° C. As can be seen, over this entire range, the power limit never degrades by more than 13 relative percent. Furthermore, this data shows that even over the range from about 20° C. to about 150° C., the power limit never degrades by more than 46 relative percent. For the reasons explained elsewhere herein, an possibly others, the methods and heat pipes of the present invention possess important and unexpected advantages, and these advantages are especially important for those applications which require operating temperatures for the heat pipe of from 20° C. to about 100° C., and from 50° C. to 100° C., such as the case with electronic components used in portable equipment like notebooks, laptops, tablet, and the like.

### Comparative Example 3—Gravity-Return Heat Pipe with R-134a as Working Fluid at 50° C.

A gravity-return heat pipe with a working fluid consisting essentially of HFC-134a and which has no capillary assist for return of the liquid phase working fluid from the condenser to the evaporator is evaluated at an operating temperature of 50° C. The required parameters, i.e. liquid fluid density, liquid fluid conductivity, liquid fluid viscosity and fluid latent heat are taken at a specified temperature, with the assumption that temperature differences along the heat pipe are negligible as described by D. A. Reay, P. A. Kew, R. J. McGlen, Heat Pipes Theory, Design and Applications, Sixth edition, UK: Elsevier, 2014. Published and publically available information for R-134a is used and particular information for the operating temperature, to the extent it is required, is estimated using Refprop 9.1, (https://www.nist.gov/refprop), developed by NIST (National Institute of Standards and Technology, USA).

The working pressure for this configuration with R-134a as the working fluid were determined to be 1317.9 KPa, which is the same value as determined for R-134a in Comparative Example 1, hence resulting in the same minimum wall thickness as reported in Comparative Example 1.

### Example 3—Gravity-return Return Heat Pipe with cis1233zd as Working Fluid at 50° C.

Comparative Example 3 is repeated, except that the working fluid consists of cis1233zd, and except that some of the physical property values for cis1233zd determined experimentally by the applicants.

The working pressure for this configuration was determined to be 140.8 KPa for cis-1233zd at 50° C., which is an order of magnitude less than the working pressure for R-134a. These results demonstrate one significant advantage according to the present invention, particularly that the heat pipe the present invention has the advantage, because of the low working pressure, of a minimum wall thickness of about 0.002 mm for a pipe diameter of 5 mm.

### Comparative Example 4—Power Limit Degradation for Gravity-Return Heat Pipes with R-134a

In order to estimate the power limit degradation of a gravity-return return heat pipe in which the working fluid consists of R-134a. The Merit number has been determined for operating temperatures ranging from about 20° C. to about 100° C. The merit number of a working fluid for a gravity-return return heat pipe can be determined by the equation set out below, in accordance with D. A. Reay, P. A. Kew, R. J. McGlen, Heat Pipes Theory, Design and Applications, Sixth edition, UK: Elsevier, 2014.

$${M}^{′} = {( \frac{γ {λ}^{3} {ρ}_{f}^{2}}{{μ}_{f}} )}^{0.25}$$

### Where,

M′ is Merit Number for gravity-return return heat pipe;
ρ_{f} is working liquid fluid density, kg/m³;
λ_{f} is working liquid fluid conductivity, W/mK;
μ_{f} is working liquid fluid viscosity, Pa S;
γ is working fluid latent heat, J/kg.

The required parameters, i.e. liquid fluid density, liquid fluid conductivity, liquid fluid viscosity and fluid latent heat are taken at a specified temperature, with the assumption that temperature differences along the heat pipe are negligible as described by D. A. Reay, P. A. Kew, R. J. McGlen, Heat Pipes Theory, Design and Applications, Sixth edition, UK: Elsevier, 2014. Published and publically available information for R-134a is used and particular information for the operating temperature, to the extent it is required, is estimated using Refprop 9.1, (https://www.nist.gov/refprop), developed by NIST (National Institute of Standards and Technology, USA). These determinations are reported in Table C4 below based on the power limit at 50° C. being the baseline from which the relative power limit at each temperature is reported:

TABLE C4

| | Power Limit Estimate, % |
|---|---|
| Operating Temp (° C.) | of Power Limit at 50° C. |
| 20 | 114% |
| 30 | 110% |
| 40 | 105% |
| 50 | 100% |
| 60 | 94% |
| 70 | 88% |
| 80 | 80% |
| 90 | 71% |
| 100 | 61% |

As can be seen from the table above, the power limit of a gravity-return return heat pipe with working fluid consisting of R-134a is estimated to undergo a rapid deterioration, on the order of 50% deterioration, as the operating temperature reaches about 100° C. For the reasons explained elsewhere herein, an possibly others, applicants have come to appreciate and expect based on this work that R-134a is likely to have disadvantages when the operating temperature for the heat pipe includes the range from about 20° C. to about 100° C., and especially in the range from 50° C. to about 100° C.

### Example 4—Power Limit Degradation for Gravity-Return Return Heat Pipes with cis1233zd

In order to estimate how the power limit of a gravity-return return heat pipe changes with temperature in which the working fluid consists of cis1233zd, the Merit number has been determined for operating temperatures ranging from about 0° C. to about 100° C. using the same process as described in connection with Comparative Example 4, and these determinations are reported in Table E4 below based on the power limit at 50° C. being the baseline from which the relative power limit at each temperature is reported:

TABLE E4

| | Power Limit Estimate, % |
|---|---|
| Operating Temp (° C.) | of Power Limit at 50° C. |
| 20 | 104% |
| 30 | 103% |
| 40 | 101% |
| 50 | 100% |
| 60 | 98% |
| 70 | 97% |
| 80 | 95% |
| 90 | 93% |
| 100 | 91% |
| 110 | 89% |
| 120 | 87% |
| 130 | 84% |
| 140 | 81% |
| 150 | 79% |
| 160 | 76% |
| 170 | 72% |
| 180 | 68% |
| 190 | 64% |
| 200 | 58% |
| 210 | 52% |

As can be seen from the table above, and based on applicants' experimental work and analysis, the power limit of a gravity-return heat pipe with working fluid consisting of cis1233zd produces a power limit profile that is dramatically and advantageously much more stable that that exhibited by R-134a in the operating temperature range from 20° C. to 100° C. As can be seen, over this entire range, the power limit never degrades by more than 9 relative percent. Furthermore, this data shows that even over the range from about 20° C. to about 210° C., the power limit never degrades by more than 48 relative percent. For the reasons explained elsewhere herein, an possibly others, the methods and heat pipes of the present invention possess important and unexpected advantages, and these advantages are especially important for those applications which require operating temperatures for the heat pipe of from 20° C. to about 100° C., and from 50° C. to 100° C., such as the case with electronic components used in portable equipment like notebooks, laptops, tablet, and the like.

### Example 5—Gravity-Return Heat Pipes Performance with Cis-1233zd

An experimental heat transfer unit in the form of a gravity-return heat pipe was built. The test unit comprised a heat pipe in having an evaporator section encased in a copper block that was attached to an electrical heater, which was thermally insulated by foam to obtain an accurate measure of heat flowing into the heat pipe. A cross-shaped aluminum fin was attached to the condensing section of the heat pipe to provide additional heat transfer surface for transfer of heat to ambient air at about 25° C. The section of the heat pipe between the evaporating section and the condensing section was also thermal insulated by the insulating foam. The tests and result reported herein were performed in accordance with Standard GB/T 14812-2008. The heat pipe was an essentially straight hollow cylinder with the following dimensions:
Outer Diameter: 10 mm
Inner Diameter: 9.4 mm
Length: 465 mm

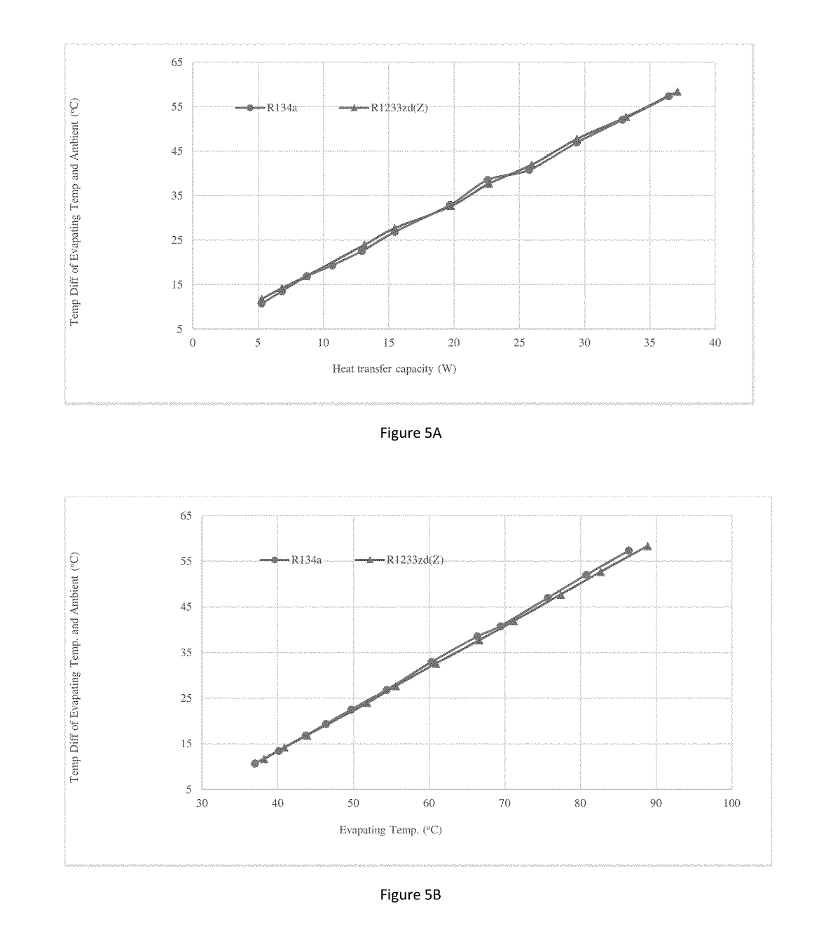

Using this test unit, applicants have determined the thermal resistance of the gravity-return heat pipe varies in an unexpectedly manner depending on the working temperature of the fluid, which is generally represented by the evaporating temperature of the heat pipe. Based on this evidence, which is shown in FIG. 5A, there is a dramatic and unexpected improvement (reduction) in thermal resistance at evaporating temperatures above 40° C., to an especially low level of 0.5° C. per watt or less at evaporating temperatures of about 50° C. and greater, and preferably from about 50° C. to about 120° C.

The unit was also operated at a series of heat inputs to the evaporator section with R-134a as the working fluid to develop a performance base-line for heat input varying from a low to high value. At each of the heat input values, the evaporating temperature during operation of the heat pipe was measured and the difference between the ambient temperature and the evaporating temperature was determined, and for convenience this difference is referred to herein as the evaporator temperature differential. In general, a lower evaporator temperature differential for a given heat input indicates better heat transfer performance. Then the unit was operated under the same conditions except with cis-1233zd as the working fluid. The results of this work are illustrated in FIG. 5BA hereof.

The results, as illustrated in FIG. 5B, show that while cis1233zd as the working fluid in the gravity-return heat pipe results in about the same or lower levels of heat transfer capacity as R-134a for evaporator temperature differentials of from 5° C. to about 60° C., at evaporator temperature differentials of above about 60° C., the heat transfer capacity is unexpectedly higher than when the working fluid is R-134a. Thus, applicants have found that the for temperature differentials of about 60 C and greater the ratio of the heat capacity of cis1233zd to R-134a in a gravity-return heat pipe is 1 or greater, while below this temperature differential, the capacity is less than 1. Thus for amibient heat sink temperatures of about 25° C., for example, applicants have found unexpectedly that cis-1233zd working fluid in a gravity-return heat pipe can dissipate more heat at an evaporating temperature above about 88° C., compared to R134a under same temperature differential. Stated another way, applicants have found that a gravity-return heat pipe comprising cis-1233zd as the working fluid shows a lower evaporator temperature differential than R-134a for a given heat transfer capacity at these evaporator conditions.

### Example 6—Capillary Heat Pipe Performance with Cis1233zd

An experimental heat transfer unit in the form of a capillary heat pipe was built. The test unit comprised a heat pipe having an evaporator section encased in a copper block that was attached to an electrical heater, which was thermally insulated by foam to obtain an accurate measure of heat flowing into the heat pipe. A cross-shaped aluminum fin was attached to the condensing section of the heat pipe to provide additional heat transfer surface for transfer of heat to ambient air at about 25° C. The section of the heat pipe between the evaporating section and the condensing section was also thermal insulated by the insulating foam. The tests and result reported herein were performed in accordance with Standard GB/T 14812-2008. The heat pipe was an essentially straight hollow having the following dimensions and including a sintered capillary component as indicated:
Outer Diameter: 10 mm
Inner Diameter: 9.4 mm
Sinter inner diameter: 8.4 mm
Sinter effective radius: 0.1^{˜}0.15 μm
Length: 465 mm

The unit was operated at a series of heat inputs to the evaporator section with R-134a as the working fluid to develop a performance base-line for heat input varying from a low to high value. At each of the heat input values, the evaporating temperature during operation of the heat pipe was measured and the difference between the ambient temperature and the evaporating temperature was determined, and for convenience this difference is referred to herein as the evaporator temperature differential. In general, a lower evaporator temperature differential for a given heat input indicates better heat transfer performance. Then the unit was operated under the same conditions except with cis-1233zd as the working fluid. The results of this work are illustrated in FIGS. 6A and 6B.

The results, as illustrated in FIGS. 6A and 6B, show that the evaporator temperature differential and heat capacity for the capillary heat pipe using cis-1233zd is unexpectedly a very close match to that of R134a, especially for evaporator temperature of from about 35° C. to about 90° C., and even more preferably from about 35° C. to about 60° C. when the ambient heat sink is at about 25° C. This unexpectedly produces the ability to utilize cis-1233zd as a drop-in replacement for R-134a in capillary heat pipe applications.

### NUMBERED EMBODIMENTS

### Numbered Embodiment 1

The use of a composition comprising at least about 60% by weight of cis 1-chloro-3,3,3-trifluoropropene, as a working fluid in a heat pipe.

### Numbered Embodiment 2

The use of numbered embodiment 1 wherein the working fluid comprises at least about 70% by weight of cis 1-chloro-3,3,3-trifluoropropene.

### Numbered Embodiment 3

The use of numbered embodiment 1 or 2 of numbered embodiment 2 wherein the working fluid comprises at least about 80% by weight of cis 1-chloro-3,3,3-trifluoropropene.

### Numbered Embodiment 4

The use of any one of numbered embodiments 1 to 3 wherein the working fluid comprises at least about 90% by weight of cis 1-chloro-3,3,3-trifluoropropene working fluid.

### Numbered Embodiment 5

The use of any one of numbered embodiments 1 to 4 wherein the working fluid comprises at least about 95% by weight of cis 1-chloro-3,3,3-trifluoropropene working fluid.

### Numbered Embodiment 6

The use of any one of numbered embodiments 1 to 5 wherein the working fluid comprises at least about 97% by weight of cis 1-chloro-3,3,3-trifluoropropene.

### Numbered Embodiment 7

The use of any one of numbered embodiments 1 to 6 wherein the working fluid comprises at least about 99.5% by weight of cis 1-chloro-3,3,3-trifluoropropene.

### Numbered Embodiment 8

The use of any one of numbered embodiments 1 to 7 wherein the working fluid consists essentially of cis 1-chloro-3,3,3-trifluoropropene.

### Numbered Embodiment 9

The use of any one of numbered embodiments 1 to 8 wherein the working fluid consists of cis 1-chloro-3,3,3-trifluoropropene.

### Numbered Embodiment 10

The use of any one of numbered embodiments 1 to 9 wherein the working fluid has a Global Warming Potential (GWP) of not greater than about 1000.

### Numbered Embodiment 11

The use of any one of numbered embodiments 1 to 10 wherein the working fluid has a Global Warming Potential (GWP) of not greater than about 750.

### Numbered Embodiment 12

The use of any one of numbered embodiments 1 to 11 wherein the working fluid has a Global Warming Potential (GWP) of not greater than about 500.

### Numbered Embodiment 13

The use of any one of numbered embodiments 1 to 12 wherein the working fluid has a Global Warming Potential (GWP) of not greater than about 150.

### Numbered Embodiment 14

The use of any one of numbered embodiments 1 to 13 wherein the working fluid has an Ozone Depletion Potential (ODP) of not greater than about 0.05.

### Numbered Embodiment 15

The use of any one of numbered embodiments 1 to 14 wherein the working fluid has an Ozone Depletion Potential (ODP) of not greater than about 0.02.

### Numbered Embodiment 16

The use of any one of numbered embodiments 1 to 15 wherein the working fluid has an Ozone Depletion Potential (ODP) of about zero.

### Numbered Embodiment 17

The use of any one of numbered embodiments 1 to 16 wherein the heat pipe is selected from a gravity-return return heat pipe, a capillary return heat pipe, a centripetal return heat pipe (or rotating heat pipe), an electrokinetic return heat pipe (electrohydrodynamic heat pipe and electro-osmotic heat pipe), a magnetic return heat pipe, an oscillating heat pipe or an osmotic heat pipe.

### Numbered Embodiment 18

The use of any one of numbered embodiments 1 to 17 wherein the heat pipe is selected from a gravity-return return heat pipe, a capillary return heat pipe, a centripetal return heat pipe (or rotating heat pipe), or a magnetic return heat pipe.

### Numbered Embodiment 19

The use of any one of numbered embodiments 1 to 17 wherein the heat pipe is a gravity-return return heat pipe.

### Numbered Embodiment 20

The use of any one of numbered embodiments 1 to 17 wherein the heat pipe is a capillary return heat pipe.

### Numbered Embodiment 21

The use of any one of numbered embodiments 1 to 20 wherein the heat pipe is provided for cooling of electric or electronic components.

### Numbered Embodiment 22

The use of numbered embodiment 21 wherein the electric or electronic component is an electric device, selected from an insulated gate bipolar transistor (IGBT), projector, or games console computer.

### Numbered Embodiment 23

The use of numbered embodiment 21 wherein the electric or electronic component is a battery, motor or power control unit (PCU) in an e-vehicle.

### Numbered Embodiment 24

The use of numbered embodiment 21 wherein the electric or electronic component is a central processing unit (CPU), graphic processing unit (GPU), memory, blade or Rack in a data centre.

### Numbered Embodiment 25

The use of numbered embodiment 21 wherein the electric or electronic component is a light emitting diode (LED) light, a quantum dot light emitting diode (QLED) TV or an organic light emitting diode (OLED).

### Numbered Embodiment 26

The use of numbered embodiment 21 wherein the electric or electronic component is a radar, a laser, satellite or space station in a spacecraft.

### Numbered Embodiment 27

The use of numbered embodiment 21 wherein the electric or electronic component is a radio frequency (RF) chip, WiFi system, base station cooling, mobile phone or a switch in a communication device.

### Numbered Embodiment 28

The use of any one of numbered embodiments 1 to 20 wherein the heat pipe is provided for recovering heat from an electric or electronic component.

### Numbered Embodiment 29

The use of numbered embodiment 28 wherein the heat pipe is provided for recovering heat from a data center.

### Numbered Embodiment 30

The use of any one of numbered embodiments 1 to 20 wherein the heat pipe is provided for use in a method of refrigeration.

### Numbered Embodiment 31

The use of numbered embodiment 30 wherein the method is defrosting a component, making ice or enhancing the uniformity of air temperature.

### Numbered Embodiment 32

The use of any one of numbered embodiments 1 to 31 wherein the heat pipe has a working temperature of ranging from about −20° C. to about 200° C.

### Numbered Embodiment 33

The use of any one of numbered embodiments 1 to 32 wherein the heat pipe has a working temperature of ranging from about 0° C. to about 140° C.

### Numbered Embodiment 34

The use of any one of numbered embodiments 1 to 33 wherein the heat pipe has a working temperature of ranging from about 20° C. to about 140° C.

### Numbered Embodiment 35

The use of any one of numbered embodiments 1 to 34 wherein the heat pipe has a working temperature of ranging from about 40° C. to about 80° C.

### Numbered Embodiment 36

The use of any one of numbered embodiments 1 to 35 wherein the heat pipe is provided for the cooling of an insulated gate bipolar transistor (IGBT), a projector, a motor, a power control unit (PCU), a light emitting diode (LED) light, a quantum dot light emitting diode (QLED), or in communication device cooling including a radio frequency (RF) chip, WiFi system, base station cooling, mobile phone or a switch or in heat management in a space craft device, including of a radar, a satellite or space station.

### Numbered Embodiment 37

A heat pipe comprising a working fluid of any one of numbered embodiments 1 to 16.

### Numbered Embodiment 38

The heat pipe of numbered embodiment 37, wherein the heat pipe is selected from a gravity-return return heat pipe, a capillary return heat pipe, a centripetal return heat pipe (or rotating heat pipe), an electrokinetic return heat pipe (electrohydrodynamic heat pipe and electro-osmotic heat pipe), a magnetic return heat pipe, an oscillating heat pipe or an osmotic heat pipe.

### Numbered Embodiment 39

The heat pipe of numbered embodiment 37 wherein the heat pipe is selected from a gravity-return return heat pipe, a capillary return heat pipe, a centripetal return heat pipe (or rotating heat pipe), or a magnetic return heat pipe.

### Numbered Embodiment 40

The heat pipe of any one of numbered embodiments 37 to 39 wherein the heat pipe is a gravity-return return heat pipe.

### Numbered Embodiment 41

The heat pipe of any one of numbered embodiments 37 to 39 wherein the heat pipe is a capillary return heat pipe.

### Numbered Embodiment 42

The heat pipe of any one of numbered embodiments 37 to 42 wherein the heat pipe has a working temperature of ranging from about −20° C. to about 200° C.

### Numbered Embodiment 43

The heat pipe of any one of numbered embodiments 37 to 43 wherein the heat pipe has a working temperature of ranging from about 0° C. to about 140° C.

### Numbered Embodiment 44

The heat pipe of any one of numbered embodiments 37 to 43 wherein the heat pipe has a working temperature of ranging from about 20° C. to about 140° C.

### Numbered Embodiment 45

The heat pipe of any one of numbered embodiments 37 to 44 wherein the heat pipe has a working temperature of ranging from about 40° C. to about 140° C.

### Numbered Embodiment 46

A method of cooling an electric or electronic component using a heat pipe as claimed in any one of numbered embodiments 37 to 45.

### Numbered Embodiment 47

The method of numbered embodiment 46, wherein the electric or electronic component is an electric device, selected from an insulated gate bipolar transistor (IGBT), projector, or games console computer.

### Numbered Embodiment 48

The method of numbered embodiment 46, wherein the electric or electronic component is a battery, motor or power control unit (PCU) in an e-vehicle.

### Numbered Embodiment 49

The method of numbered embodiment 46, wherein the electric or electronic component is a central processing unit (CPU), graphic processing unit (GPU), memory, blade or Rack in a data centre.

### Numbered Embodiment 50

The method of numbered embodiment 46, wherein the electric or electronic component is a light emitting diode (LED) light, a quantum dot light emitting diode (QLED) TV or an organic light emitting diode (OLED).

### Numbered Embodiment 51

The method of numbered embodiment 46, wherein the electric or electronic component is a radar, a laser, satellite or space station in a spacecraft.

### Numbered Embodiment 52

The method of numbered embodiment 46, wherein the electric or electronic component is a radio frequency (RF) chip, WiFi system, base station cooling, mobile phone or a switch in a communication device.

### Numbered Embodiment 53

A method of recovering heat from an electric or electronic component using a heat pipe as claimed in any one of numbered embodiments 37 to 45.

### Numbered Embodiment 54

The method of numbered embodiment 53, wherein the method of recovering heat particularly relates data center heat recovery between hot fresh air and cold inner air.

### Numbered Embodiment 55

A method of refrigeration using a heat pipe as claimed in any one of numbered embodiments 37 to 45.

### Numbered Embodiment 56

The method of numbered embodiment 55, wherein the method is defrosting a component, making ice or enhancing the cooling or uniformity of air temperature.

### Numbered Embodiment 57

A method of preparing a heat pipe, said method comprising filling the heat pipe with a composition as claimed in any one of numbered embodiments 1 to 16.

### Numbered Embodiment 58

A method of transferring heat, comprising: (a) providing a heat pipe comprising an evaporating section containing a liquid working fluid comprising at least about 60% by weight of cis 1-chloro-3,3,3-trifluoropropene and a condensing section containing a working fluid vapor comprising greater than 60% by weight of cis 1-chloro-3,3,3-trifluoropropene; (b) placing said evaporating section in thermal communication with a body, fluid, surface or the like to be cooled; and (c) placing said condensing section in thermal communication with a body, fluid, surface or the like to be heated.

### Numbered Embodiment 59

The method of numbered embodiment 58, wherein the liquid working fluid and the vapour working fluid each comprise at least about 70% by weight of cis 1-chloro-3,3,3-trifluoropropene.

### Numbered Embodiment 60

The method of numbered embodiment 59, wherein the liquid working fluid and the vapour working fluid each comprise at least about 80% by weight of cis 1-chloro-3,3,3-trifluoropropene.

### Numbered Embodiment 61

The method of numbered embodiment 60, wherein the liquid working fluid and the vapour working fluid each comprise at least about 90% by weight of cis 1-chloro-3,3,3-trifluoropropene.

### Numbered Embodiment 62

The method of numbered embodiment 61, wherein the liquid working fluid and the vapour working fluid each comprise at least about 95% by weight of cis 1-chloro-3,3,3-trifluoropropene.

### Numbered Embodiment 63

The method of numbered embodiment 62, wherein the liquid working fluid and the vapour working fluid each comprise at least about 97% by weight of cis 1-chloro-3,3,3-trifluoropropene.

### Numbered Embodiment 64

The method of numbered embodiment 63, wherein the liquid working fluid and the vapour working fluid each comprise at least about 99.5% by weight of cis 1-chloro-3,3,3-trifluoropropene.

### Numbered Embodiment 65

The method of numbered embodiment 64, wherein the liquid working fluid and the vapour working fluid each consist essentially of cis 1-chloro-3,3,3-trifluoropropene.

### Numbered Embodiment 66

The method of numbered embodiment 65, wherein the liquid working fluid and the vapour working fluid each consist of cis 1-chloro-3,3,3-trifluoropropene.

### Numbered Embodiment 67

The method of numbered embodiments 58 to 66, wherein the heat pipe is selected from a gravity-return return heat pipe, a capillary return heat pipe, a centripetal return heat pipe (or rotating heat pipe), an electrokinetic return heat pipe (electrohydrodynamic heat pipe and electro-osmotic heat pipe), a magnetic return heat pipe, an oscillating heat pipe or an osmotic heat pipe.

### Numbered Embodiment 68

The method of numbered embodiment 67 wherein the heat pipe is selected from a gravity-return return heat pipe, a capillary return heat pipe, a centripetal return heat pipe (or rotating heat pipe), or a magnetic return heat pipe.

### Numbered Embodiment 69

The method of any one of numbered embodiments 67 or 68 wherein the heat pipe is a gravity-return return heat pipe.

### Numbered Embodiment 70

The method of any one of numbered embodiments 67 or 68 wherein the heat pipe is a capillary return heat pipe.

### Numbered Embodiment 71

The method of any one of numbered embodiments 67 to 70 wherein the heat pipe has a working temperature of ranging from about −20° C. to about 200° C.

### Numbered Embodiment 72

The method of any one of numbered embodiments 67 to 71 wherein the heat pipe has a working temperature of ranging from about 0° C. to about 140° C.

### Numbered Embodiment 73

The method of any one of numbered embodiments 67 to 72 wherein the heat pipe has a working temperature of ranging from about 20° C. to about 140° C.

### Numbered Embodiment 74

The method of any one of numbered embodiments 67 to 73 wherein the heat pipe has a working temperature of ranging from about 40° C. to about 140° C.

### Numbered Embodiment 75

The method of any one of numbered embodiments 58 to 74 wherein the power limit of the heat pipe operating at about 50° C. is not degraded by more than 40% relative percent over the operating temperature range of from about 20° C. to about 100° C., preferably by not more than 30% relative percent over the operating temperature range of from about 20° C. to about 100° C., more preferably by not more than 25% relative percent over the operating temperature range of from about 20° C. to about 100° C., more preferably by not more than 20% relative percent over the operating temperature range of from about 20° C. to about 100° C., more preferably by not more than 15% relative percent over the operating temperature range of from about 20° C. to about 100° C., more preferably by not more than 10% relative percent over the operating temperature range of from about 20° C. to about 100° C.

### Numbered Embodiment 76

An electronic device that includes components that operate at temperatures above ambient, comprising: (a) an electric or electronic component that in operation generates heat and raises the temperature of said component to above ambient; and (b) a heat pipe comprising an evaporating section containing a liquid working fluid comprising greater than 60% by weight of cis 1-chloro-3,3,3-trifluoropropene and a condensing section containing a vaporous working fluid comprising greater than 60% by weight of cis 1-chloro-3,3,3-trifluoropropene, wherein said evaporating section is thermally connected to said electronic component and wherein said condenser section is thermally connected to a heat sink, wherein said heat sink is at a temperature of from about 20° C. to about 100° C., more preferably at a temperature from about 50° C. to about 100° C.

### Numbered Embodiment 77

The electronic device of numbered embodiment 76, wherein the liquid working fluid and the vapour working fluid are as defined in numbered embodiments 59 to 65.

### Numbered Embodiment 78

The electronic device of numbered embodiment 76 or 77, wherein the operating temperature range of the heat pipe is from about 20° C. to about 100° C.

### Numbered Embodiment 79

The electronic device of numbered embodiments 76 to 78, wherein the heat pipe is as defined in any of numbered embodiments 67 to 74.

### Numbered Embodiment 80

The electronic device of numbered embodiments 76 to 79, wherein the electric or electronic component is as defined in any of numbered embodiments 48 to 52.

### Numbered Embodiment 81

The electronic device of numbered embodiments 76 to 80, wherein the electronic device is as defined in numbered embodiment 47.

### Numbered Embodiment 81

The electronic device of numbered embodiments 76 to 80, wherein the power limit of the heat pipe operating at about 50° C. is not degraded by more than 40% relative percent over the operating temperature range of from about 20° C. to about 100° C., preferably by not more than 30% relative percent over the operating temperature range of from about 20° C. to about 100° C., more preferably by not more than 25% relative percent over the operating temperature range of from about 20° C. to about 100° C., more preferably by not more than 20% relative percent over the operating temperature range of from about 20° C. to about 100° C., more preferably by not more than 15% relative percent over the operating temperature range of from about 20° C. to about 100° C., more preferably by not more than 10% relative percent over the operating temperature range of from about 20° C. to about 100° C.

What is claimed is:

1. A use of a working fluid comprising at least about 60% by weight of cis 1-chloro-3,3,3-trifluoropropene in a heat pipe.

2. The use as claimed in claim 1 wherein the working fluid comprises at least about 90% by weight of cis 1-chloro-3,3,3-trifluoropropene.

3. The use as claimed in claim 1 wherein the working fluid comprises at least about 95% by weight of cis 1-chloro-3,3,3-trifluoropropene.

4. The use as claimed in claim 1 wherein the working fluid comprises at least about 97% by weight of cis 1-chloro-3,3,3-trifluoropropene.

5. The use as claimed in claim 1 wherein the working fluid comprises at least about 99.5% by weight of cis 1-chloro-3,3,3-trifluoropropene.

6. The use as claimed in claim 1 wherein the working fluid consists essentially of cis 1-chloro-3,3,3-trifluoropropene.

7. The use as claimed in claim 1 wherein the heat pipe is selected from a gravity-return return heat pipe, a capillary return heat pipe, a centripetal return heat pipe (or rotating heat pipe), an electrokinetic return heat pipe, a magnetic return heat pipe, an oscillating heat pipe or an osmotic heat pipe.

8. The use as claimed in claim 1 wherein the heat pipe is a gravity-return return heat pipe or a capillary return heat pipe.

9. A heat pipe comprising a working fluid, as defined in claim 1.

10. The heat pipe of claim 9 wherein the heat pipe is selected from a gravity-return return heat pipe, a capillary return heat pipe, a centripetal return heat pipe (or rotating heat pipe), an electrokinetic return heat pipe, a magnetic return heat pipe, an oscillating heat pipe or an osmotic heat pipe.

11. A gravity-return return heat pipe comprising a working fluid as claimed in claim 1.

12. A capillary return heat pipe comprising a working fluid as claimed in claim 1.

13. A method of cooling an electric or electronic component using a heat pipe as claimed in claim 9.
